(19) United States
(12) Patent Application Publication
(10) Pub. No.: US 2023/0260796 A1
(43) Pub. Date: Aug. 17, 2023

(54) METHOD OF MANUFACTURING SEMICONDUCTOR DEVICES

(71) Applicant: TAIWAN SEMICONDUCTOR MANUFACTURING COMPANY, LTD., Hsinchu (TW)

(72) Inventors: Yu-Jen CHANG, New Taipei City (TW); Chih-Yang CHEN, Hsinchu City (TW); Hua Feng CHEN, Hsinchu City (TW); Kuo-Hua PAN, Hsinchu City (TW); Mu-Chi CHIANG, Hsinchu (TW)

(21) Appl. No.: 17/752,445

(22) Filed: May 24, 2022

Related U.S. Application Data
(60) Provisional application No. 63/311,323, filed on Feb. 17, 2022.

(51) Int. Cl. H01L 21/308; G06F 30/392

(52) U.S. Cl. CPC H01L 21/3086; G06F 30/392; H01L 21/76224

(57) ABSTRACT

In a method of manufacturing a semiconductor device, an initial pattern layout is obtained. The initial pattern layout incudes fin patterns which include active fin patterns to be formed as active fin structures and dummy fin patterns not to be formed as actual fin structures or to be removed. The locations of the fin patterns are modified, as follows. A space between adjacent active fin patterns is increased by a first amount, a space between the dummy fin patterns is decreased by a second amount, and a space between one of the dummy fin patterns and one of the active fin patterns adjacent to the one of the dummy fin patterns is decreased by a third amount. Mandrel patterns are placed so that the fin patterns of which locations are modified are placed along longitudinal edges of the mandrel patterns.

### RELATED APPLICATION

This application claims priority to U.S. Provisional Patent Application No. 63/311,323 filed on Feb. 17, 2022, the entire disclosure of which is incorporated herein by reference.

### BACKGROUND

As the semiconductor industry has progressed into nanometer technology process nodes in pursuit of higher device density, higher performance, lower power consumption and lower costs, challenges from both fabrication and design issues have resulted in the development of three-dimensional designs, such as a fin field effect transistor (Fin FET). In a Fin FET device, it is possible to utilize additional sidewalls and to suppress a short channel effect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1, 2, 3, 4, 5, 6, 7, 8, 9, 10, 11, 12, 13, 14, 15, 16, 17, 18, 19A, 19B, 20 and 21 show cross sectional views of various stages of a sequential manufacturing operation for a semiconductor device according to an embodiment of the present disclosure.

FIG. 22A is a plan view corresponding to FIG. 5 and FIG. 22B is a layout view of mandrel patterns according to an embodiment of the present disclosure.

FIGS. 23A, 23B, 23C, 23D and 23E show layout pattern modifications for the mandrel patterns and FIG. 23F shows a flow chart of manufacturing a photo mask according to an embodiment of the present disclosure.

FIGS. 24A, 24B and 24C show cross sectional views of fin cut operations according to an embodiment of the present disclosure.

FIGS. 25A and 25B show a layout pattern modification for the mandrel patterns according to an embodiment of the present disclosure.

FIGS. 26A and 26B show a layout pattern modification for the mandrel patterns according to an embodiment of the present disclosure.

FIGS. 27A and 27B show a layout pattern modification for the mandrel patterns according to an embodiment of the present disclosure.

FIGS. 28A, 28B, 28C and 28D show a layout pattern modification for the mandrel patterns according to an embodiment of the present disclosure.

FIGS. 29A, 29B, 29C and 29D show a layout pattern modification for the mandrel patterns according to an embodiment of the present disclosure.

FIGS. 30A, 30B, 30C and 30D show a layout pattern modification for the mandrel patterns according to an embodiment of the present disclosure.

FIGS. 31A, 31B, 31C and 31D show a layout pattern modification for the mandrel patterns according to an embodiment of the present disclosure.

FIGS. 32A, 32B, 32C and 32D show a layout pattern modification for the mandrel patterns according to an embodiment of the present disclosure.

FIGS. 33A, 33B, 33C and 33DB show layout pattern modifications for the mandrel patterns and FIG. 33E shows a flow chart of manufacturing a photo mask according to an embodiment of the present disclosure.

FIG. 34A shows a flowchart of a method of making a semiconductor device, and FIGS. 34B, 34C, 34D, 34E and 34F show a sequential manufacturing operation of a method of making a semiconductor device in accordance with embodiments of present disclosure.

FIGS. 35A and 35B illustrate an apparatus for manufacturing a lithographic mask for a semiconductor circuit in accordance with some embodiments of the disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “comprising” or “consisting of.”

Fin structures used in FinFETs are manufactured by various patterning methods. When a critical dimension (CD) of a fin structure decreases below 20 nm, for example, it is generally difficult to directly form a pattern having such a small dimension by a single optical lithography process, and some fine patterning processes have been developed. For example, the fin structures may be patterned using double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer, which is often referred to as a mandrel pattern, is formed over a substrate and patterned using a photolithography process. Spacers are formed alongside the patterned sacrificial layer using a self-aligned process. The sacrificial layer is then removed, and the remaining spacers may then be used to pattern the fin structures. This operation may be repeated to manufacture desired fin patterns.

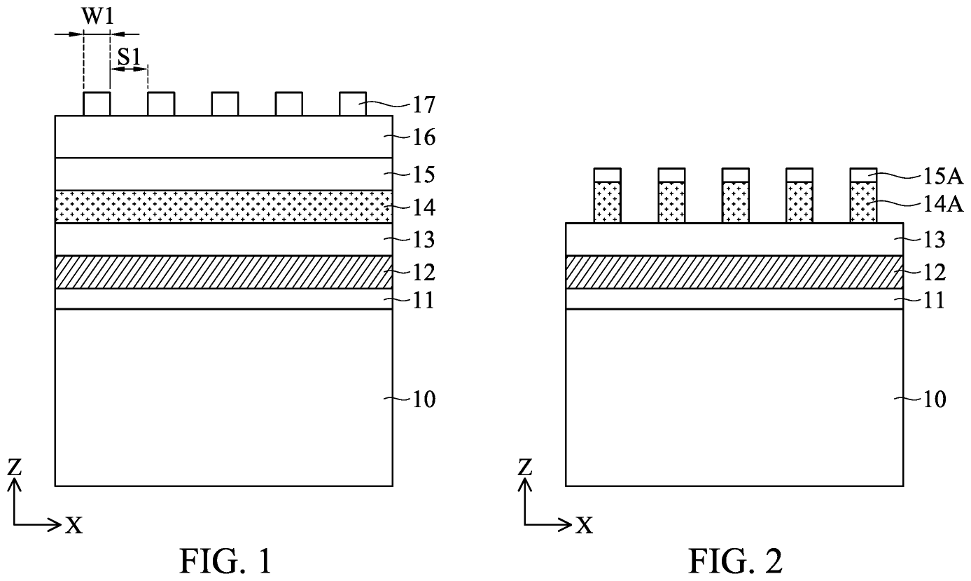

FIGS. 1-21 show various stages of a sequential manufacturing process of a semiconductor FinFET device according to embodiments of the present disclosure. It is understood that additional operations may be provided before, during, and after processes shown by FIGS. 1-21, and some of the operations described below can be replaced or eliminated in additional embodiments of the method. The order of the operations can be changed in some embodiments. In some embodiments, the semiconductor device is a gate-all-around (GAA) FET using nanowires or nanosheets.

As shown in FIG. 1, multiple layers for hard masks are formed over a substrate 10 to be patterned into fin structures. In some embodiments, the substrate 10 is a silicon substrate. Alternatively, the substrate 10 may comprise another elementary semiconductor, such as germanium; a compound semiconductor including Group IV-IV compound semiconductors, such as SiC and SiGe; Group III-V compound semiconductors, such as GaAs, GaP, GaN, InP, InAs, InSb, GaAsP, AlGaN, AlInAs, AlGaAs, GaInAs, GaInP, and/or GaInAsP; or combinations thereof. In some embodiments, in a case of manufacturing a gate-all-around (GAA) FET, multiple layers of first semiconductor layer (e.g., SiGe layers) and second semiconductor layers (e.g., Si layers) are alternately formed over the substrate 10, and the multiple layers and a part of the substrate 10 are formed into a fin structure.

In some embodiments, a first layer 11 is formed over the substrate 10. In some embodiments, the first layer 11 is a pad silicon oxide layer formed by, for example, a thermal oxidation process or a chemical vapor deposition (CVD) process. In some embodiments, the thickness of the first layer 11 is in a range from about 1 nm to about 5 nm. Further, in some embodiments, a second layer 12 made of a different material than the first layer 11 is formed over the first layer 11. In some embodiments, the second layer 12 is a second pad layer or a hard mask layer including, for example, silicon nitride formed by, for example, a CVD or atomic layer deposition (ALD) process. In some embodiments, the thickness of the second layer 12 is in a range from about 2 nm to about 20 nm.

Further, in some embodiments, a third layer 13 made of a different material than the second layer 12 is formed over the second layer 12. In some embodiments, the third layer 13 is a hard mask layer formed by, for example, a CVD process. In some embodiments, the third layer 13 includes silicon oxide, SiON, SiOC, SiOCN, aluminum oxide or any other suitable material. In some embodiments, the thickness of the third layer 13 is in a range from about 5 nm to about 30 nm. In some embodiments, the third layer 13 is made of a same material as or a different material than the first layer 11.

Then, a fourth layer 14 made of a different material than the third layer 13 is formed over the third layer 13 in some embodiments. In some embodiments, the fourth layer 14 is a sacrificial layer for a mandrel pattern formed by, for example, a CVD process. In some embodiments, the fourth layer 14 includes amorphous or polycrystalline Si, SiGe or Ge, silicon oxide, SiOC, SiON, SiOCN or any other suitable material. In certain embodiments, non-doped poly silicon is used as the fourth layer 14. In some embodiments, the thickness of the fourth layer 14 is in a range from about 5 nm to about 30 nm. Further, in some embodiments, a fifth layer 15 made of a different material than the fourth layer 14 is formed over the fourth layer 14. In some embodiments, the fifth layer 15 is a hard mask layer formed by, for example, a CVD process. In some embodiments, the fifth layer 15 includes silicon oxide, silicon nitride, SiON, SiOC, SiOCN or any other suitable material. In certain embodiments, silicon nitride is used as the fifth layer 15. In some embodiments, the thickness of the fifth layer 15 is in a range from about 4 nm to about 20 nm.

Then, an organic bottom antireflective coating (BARC) layer 16 is formed over the fifth layer 15, and a photo resist layer is formed over the BARC layer 16 in some embodiments. Then, the photo resist layer is patterned by using a lithography operation, thereby forming a first mask pattern, i.e., a photo resist pattern 17, as shown in FIG. 1. In some embodiments, a width W1 of the photo resist pattern 17 is in a range from about 20 nm to about 100 nm and a space S1 is in a range from about 30 nm to about 200 nm, depending on design requirements. In some embodiments, the space S1 is greater than the width W1. Each of the photo resist patterns 17 corresponds to a mandrel pattern as described below.

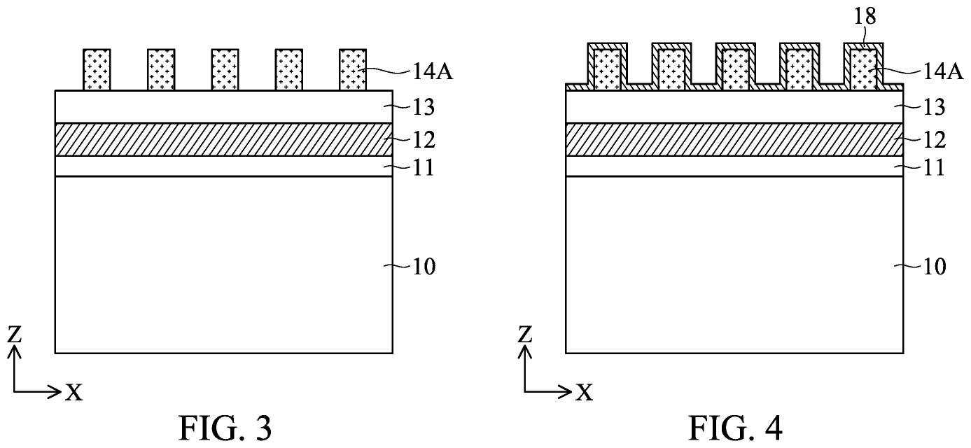

Then, the BARC layer 16 is patterned by using the photo resist pattern 17 as an etching mask, and the fifth layer 15 is further patterned using the patterned BARC layer 16 (and the photo resist pattern 17) as an etching mask, thereby forming a first hard mask pattern 15A. Then, the fourth layer (sacrificial layer) 14 is patterned using one or more plasma dry etching operations by using the first hard mask pattern 15A, thereby forming a mandrel pattern 14A, as shown in FIG. 2. Then, the first hard mask pattern 15A is removed as shown in FIG. 3 by wet and/or dry etching.

Then, as shown in FIG. 4, a sixth layer 18 for sidewall spacers is conformally formed on the mandrel pattern 14A and the exposed third layer 13. In some embodiments, the sixth layer 18 is made of a different material than the mandrel patterns 14A and the third layer 13, and includes silicon nitride, SiON, SiCN or any other suitable material. In certain embodiments, a silicon nitride layer is used as the sixth layer 18. In some embodiments, the thickness of the sixth layer 18 is in a range from about 5 nm to about 15 nm, and is in a range from about 7 nm to about 12 nm in other embodiments, depending on design requirements and/or process requirements. In some embodiments, the sixth layer 18 is formed by an ALD process.

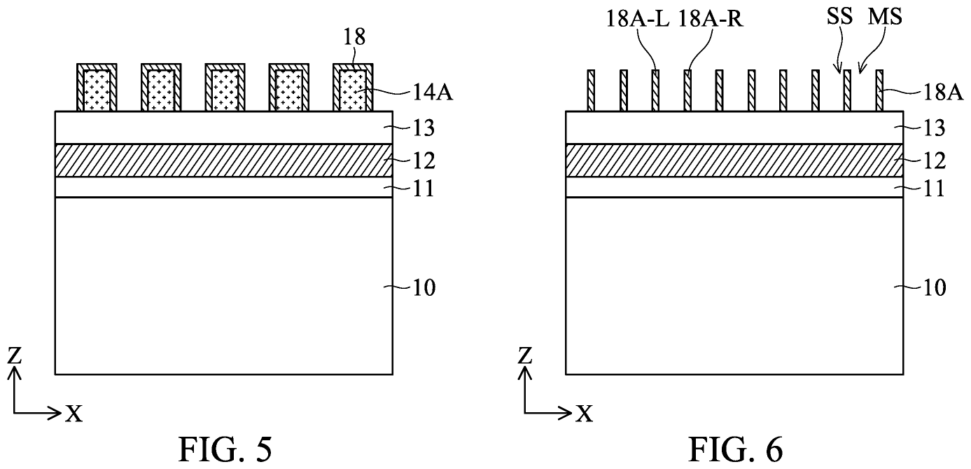

Next, as shown in FIG. 5, anisotropic etching is performed on the sixth layer 18 to remove the horizontal portions of the sixth layer 18 deposited on the top of the mandrel patterns 14A and the third layer 13 between the adjacent mandrel patterns 14A. As the result of the anisotropic etching, the sixth layer 18 remains as sidewall spacers 18A disposed on opposing side faces of the mandrel patterns 14A as shown in FIG. 5. The remaining thickness measured in the horizontal direction X corresponds to the width of the fin structure subsequently formed.

Then, as shown in FIG. 6, the mandrel patterns 14A are removed by one or more dry and/or wet etching operations, thereby leaving the sidewall spacers 18A as second hard mask patterns. As shown in FIG. 6, a mandrel-space MS is a space from which a mandrel pattern 14A is removed and which is formed by a left sidewall 18A-L and a right sidewall 18A-R, and a spacer-space SS is a space where no a mandrel pattern 14A existed and which is formed by a right sidewall 18A-R and a left sidewall 18A-L. In some embodiments, the width and/or space of the mandrel patterns 14A and/or the thickness of the sixth layer 18 are adjusted or set such that the second hard mask patterns 18A have a substantially constant pitch. In some embodiments, a variation of the pitches is more than zero and less than about 0.5 nm. In some embodiments, the space between the second hard mask patterns 18A at the mandrel-space MS is equal to or greater than the space between the second hard mask patterns 18A at the spacer-space SS, and in other embodiments, the space between the second hard mask patterns 18A at the mandrel-space MS is smaller than the space between the second hard mask patterns 18A at the spacer-space SS.

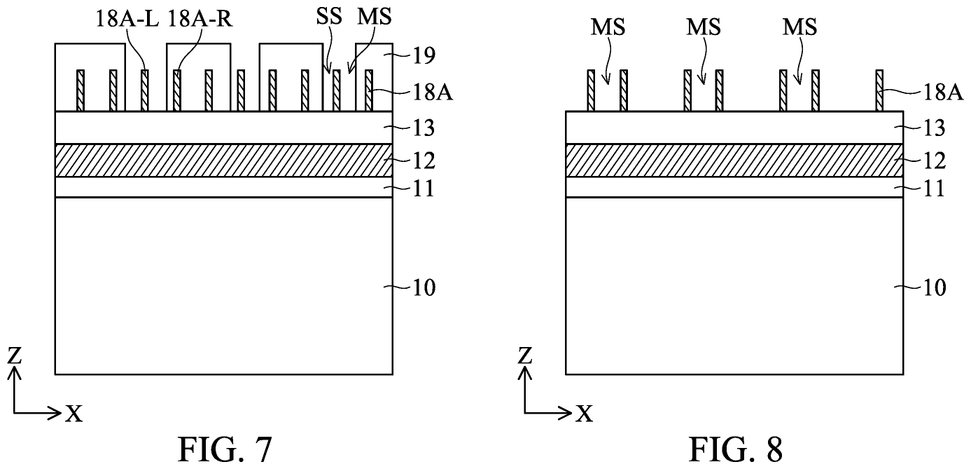

Next, as shown in FIG. 7, a second mask pattern, such as a photo resist pattern 19, is formed over the second hard mask patterns 18A, and portions of the second hard mask patterns are removed and the second hard mask patterns are cut into pieces by one or more etching operations. A mandrel pattern has a definite length, and thus, the second hard mask pattern 18A is formed to surround the mandrel pattern (i.e., a ring or a frame shape). Thus, a part of the second hard mask pattern 18A formed on a short side extending in the X direction of the mandrel pattern is removed, thereby forming a pair of second hard mask patterns 18A extending in the Y direction. Further, one or more second hard mask patterns 18A extending in the Y direction are removed depending of the circuit layout.

As described later, the cut second hard mask patterns 18A correspond to fin structures used in FinFETs. After the etching operation, the mask pattern 19 is removed as shown in FIG. 8. In some embodiments, the remaining hard mask patterns 18A constitute mandrel-spaces MS, as shown in FIG. 8.

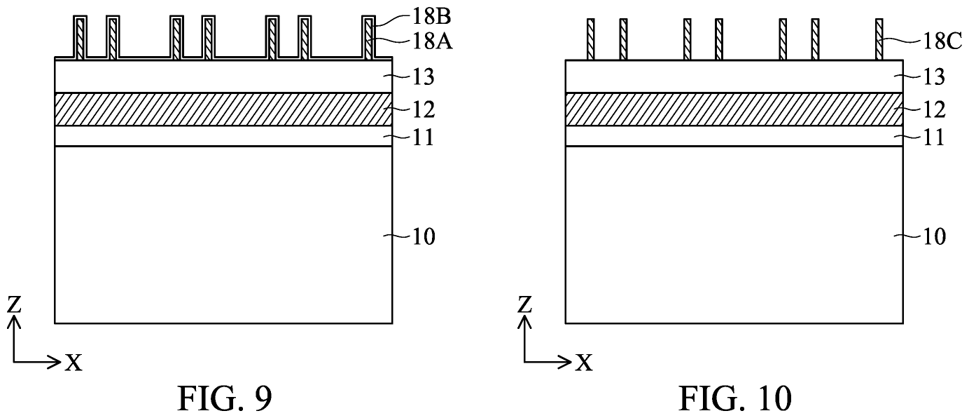

Then, as shown in FIG. 9, an optional additional hard mask layer 18B is conformally formed over the second hard mask layer 18A to adjust thickness (width) of the second hard mask layer 18A. In some embodiments, the additional hard mask layer 18B is made of the same or similar material to the second hard mask layer 18A, and includes silicon nitride, SiON, SiCN or any other suitable material, formed by an ALD process. In certain embodiments, silicon nitride is used as the additional hard mask layer 18B. In some embodiments, the thickness of the additional hard mask layer 18B is in a range from about 1 nm to about 2 nm. After the additional hard mask layer 18B is formed, anisotropic etching is performed to remove horizontal part of the deposited additional hard mask layer 18B in some embodiments.

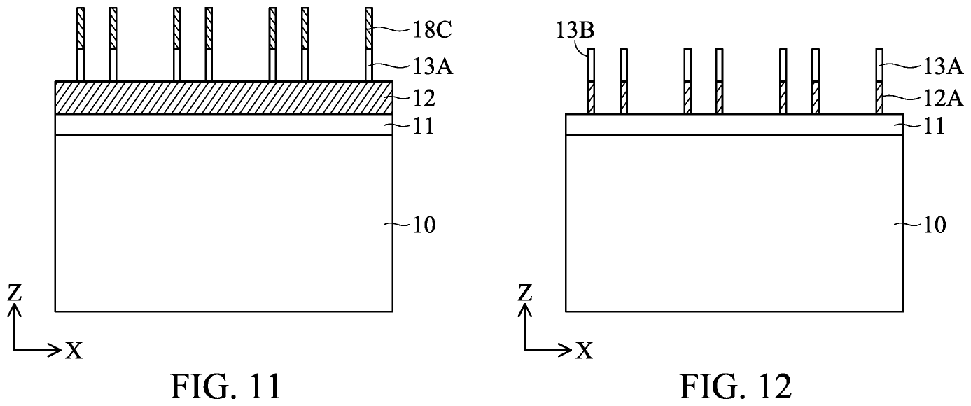

In FIG. 10, the combination of the second hard mask pattern 18A and the additional hard mask layer 18B are shown as hard mask pattern 18C. Then, as shown in FIG. 11, the third layer 13 is patterned by one or more plasma dry etching by using the hard mask pattern 18C as an etching mask, thereby forming a third hard mask pattern 13A. Then, the hard mask pattern 18C is removed by one or more dry and/or wet etching operations.

Further, the second layer 12 is patterned by one or more plasma dry etching operation using the third hard mask pattern 13A as an etching mask, thereby forming a fourth hard mask pattern 12A. In some embodiments, after the patterning operation, an additional hard mask layer 13B is conformally formed over the third hard mask pattern 13A and fourth hard mask pattern 12A to adjust thickness (width) of the hard mask pattern. In some embodiments, the additional hard mask layer 13B is made of the same or similar material as the third hard mask layer 13A, and includes silicon oxide, SiON, SiOC or any other suitable material, formed by an ALD process. In certain embodiments, silicon oxide is used as the additional hard mask layer 13B. In some embodiments, the thickness of the additional hard mask layer 13B is in a range from about 0.5 nm to about 2 nm. After the additional hard mask layer 13B is formed, anisotropic etching is performed to remove horizontal part of the deposited additional hard mask layer 13B in some embodiments.

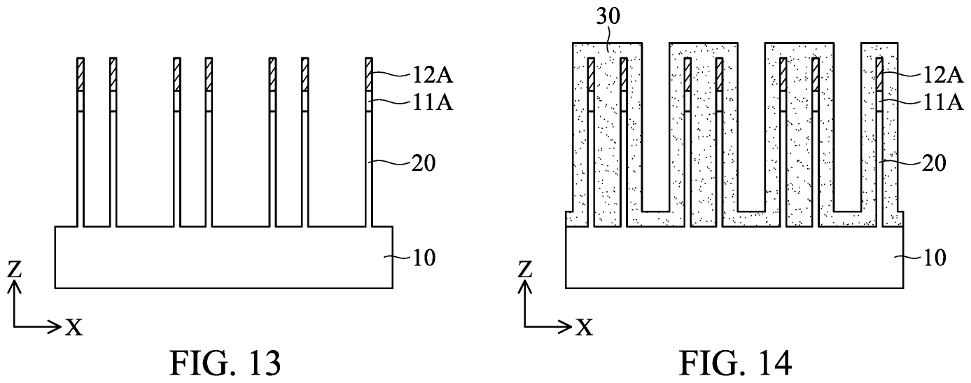

Then, the first layer 12 and the substrate 10 are patterned by one or more plasma dry etching using the hard mask pattern 13A and/or 12A as an etching mask, thereby forming fin structures 20 as shown in FIG. 13. In some embodiments, after the patterning etching, the hard mask pattern 12A and a patterned first layer 11A remain on the top of each of the fin structures 20. In some embodiments, the hard mask pattern 13A is removed during and/or after the patterning of the substrate 10.

After the fin structures 20 are formed, a blanket first dielectric layer 30 is formed over the fin structures 2 as shown in FIG. 14. The blanket first dielectric layer 30 includes one or more layers of insulating materials such as silicon oxide, silicon oxynitride, silicon nitride, SiOC, SiCN or SiOCN, formed by LPCVD (low pressure chemical vapor deposition), plasma-CVD or atomic layer deposition (ALD), or any other suitable film formation method. In certain embodiments, silicon oxide is used as the first dielectric layer 30. In some embodiments, as shown in FIG. 14, the first dielectric layer 30 is conformally formed over the fin structures 20 such that a narrow space between adjacent fin structures is fully filled by the first dielectric layer 30 and a wider space between adjacent fin structures is not fully formed thereby forming a space. In some embodiments, the width of the space is in a range of about 5 nm to about 40 nm in some embodiments, and is in a range of about 7 nm to about 15 nm in certain embodiments.

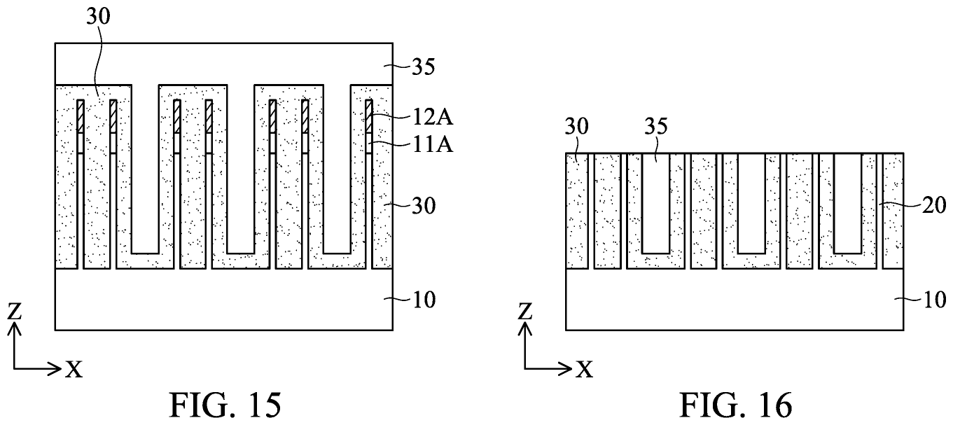

After the first dielectric layer 30 is formed, a second dielectric layer 35 is formed over the first dielectric layer 30, as shown in FIG. 15. The material of the second dielectric layer 35 is different from the material of the first dielectric layer 30. In some embodiments, the second dielectric layer 35 includes one or more layers of insulating materials such as silicon oxide, silicon oxynitride or silicon nitride, SiOC, SiCN or SiOCN formed by LPCVD, plasma-CVD or ALD, or any other suitable film formation method. In some embodiments, the second dielectric layer 35 includes a first layer made of silicon nitride and a second layer made of silicon oxide.

In some embodiments, after the second dielectric layer 35 is formed, a planarization operation, such as an etch-back process or a chemical mechanical polishing (CMP) process, is performed to planarize the upper surface of the second dielectric layer 35, the upper surface of the first dielectric layer 30 and hard mask layers 11A and 12A, so that the top of the fin structures 20 is exposed, as shown in FIG. 16.

In some embodiments, after the second dielectric layer 35 is formed, over the first dielectric layer 30, a planarization operation is performed to planarize the upper surface of the second dielectric layer 35, so that the top of the first dielectric layer 30 is exposed. Next, the second dielectric layer 35 is recessed down below the top of the fin structures 20 by using a suitable dry and/or wet etching operation, so that a second space is formed over the recessed second dielectric layer 35. In some embodiments, the upper surface of the recessed second dielectric layer 35 has a V-shape or a U-shape. Further, after the second dielectric layer 35 is recessed, a third dielectric layer is formed over the first dielectric layer 30 and the recessed second dielectric layer 35. The material of the third dielectric layer is different from the materials of the first dielectric layer 30 and the second dielectric layer 35 in some embodiments. In some embodiments, the third dielectric layer includes one or more insulating material layers. In some embodiments, at least one of the insulating material layers has a lower etching rate than the second dielectric layer 35 against a polysilicon etching. In some embodiments, the third dielectric layer includes a high-k dielectric material. In some embodiments, the third dielectric layer includes a dielectric material having a higher dielectric constant (k) than the second dielectric layer 35 and/or the first dielectric layer 30. When the upper surface of the recessed second dielectric layer 35 has a V-shape or a U-shape, the bottom of the third dielectric layer has a V-shape or a U-shape. In some embodiments, the third dielectric layer includes one or more of non-doped hafnium oxide (e.g., HfOₓ, 0<x≤2), hafnium oxide doped with one or more other elements (e.g., HfSiO, HfSiON, HfTaO, HfTiO or HfZrO), zirconium oxide, aluminum oxide, titanium oxide, and a hafnium dioxide-alumina (HfO₂—Al₂O₃) alloy. In certain embodiments, hafnium oxide (HfOₓ) is used as the third dielectric layer. The third dielectric layer can be formed by LPCVD, plasma-CVD or ALD, or any other suitable film formation method. In some embodiments, the second dielectric layer 35 is made of silicon nitride. The third dielectric layer fully fills the second space and covers the top of the first dielectric layer 30, in some embodiments. In some embodiments, after the third dielectric layer is formed, the planarization operation, such as an etch-back process or a CMP process, is performed to planarize the upper surface of the third dielectric layer, the upper surface of the second dielectric layer 35, the upper surface of the first dielectric layer 30 and hard mask layers 11A and 12A, so that the top of the fin structure 20 is exposed, as shown in FIG. 16.

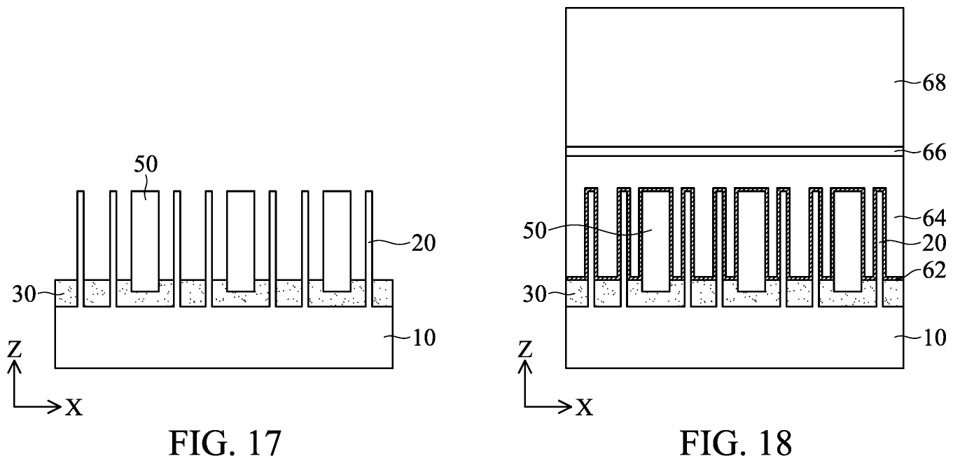

Then, the first dielectric layer 30 is recessed down below the top of the fin structures 20 by using a suitable dry and/or wet etching operation so that an upper portion of a wall fin structure (hybrid fin structure) 50 and the upper portion of the fin structures are exposed, as shown in FIG. 17. The recessed first dielectric layer 30 functions as an isolation insulating layer (e.g., shallow trench isolation (STI)) to electrically isolate one fin structure from adjacent fin structures.

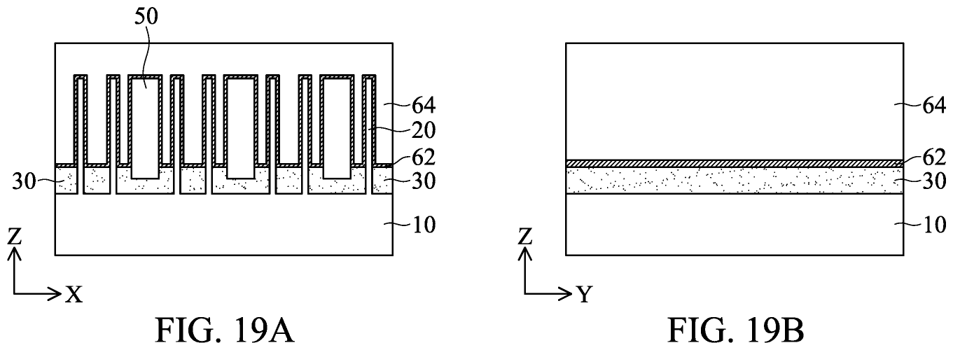

Subsequently, a sacrificial gate structure is formed over channel regions of the fin structures 20 and the wall fins 50. As shown in FIG. 18, a blanket layer 62 for the sacrificial gate dielectric layer and a blanket polysilicon layer 64 are formed over the isolation insulating layer 30, the fin structures 20 and the wall fin structure 50. In some embodiments, an etching stop layer 66 (e.g., silicon oxide layer) and an upper polysilicon layer 68 is formed over the etching stop layer 66, as shown in FIG. 18. Then, one or more planarization operations, e.g., CMP operations, are performed to planarize the first blanket layer 84, as shown in FIGS. 19A and 19B. FIG. 19A is a cross sectional view along the X direction, and FIG. 19B is a cross sectional view along the Y direction between adjacent fin structures.

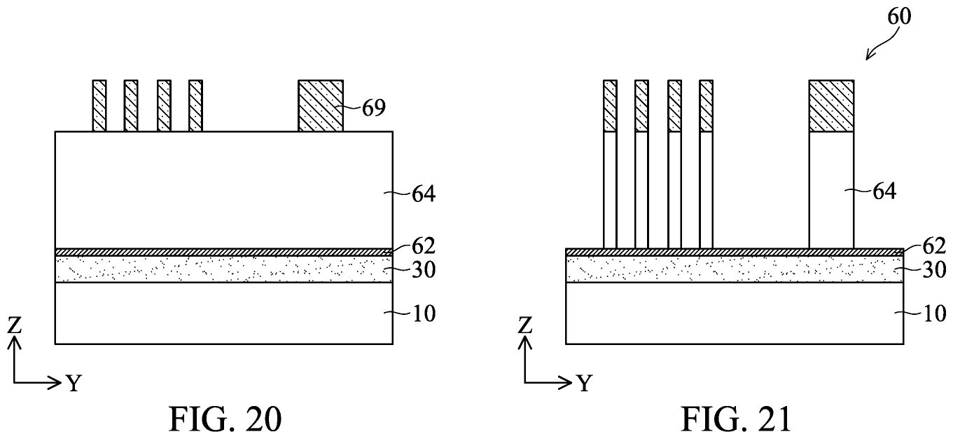

Then, one or more patterning operations are performed to obtain the sacrificial gate structures 60 as shown in FIGS. 20 and 21. The patterning of the polysilicon layer is performed by forming a hard mask pattern 69, for example, including a silicon nitride layer and a silicon oxide layer, as shown in FIG. 20, and patterning the polysilicon layer 64 by using the hard mask pattern 60 as an etching mask, as shown in FIG. 21.

Further, gate sidewall, gate sidewall spacers are formed on side faces of the sacrificial gate structures 60. An insulating material layer for the gate sidewall spacers is formed over the sacrificial gate structure 60. The insulating material layer is deposited in a conformal manner so that it has substantially equal thicknesses on vertical surfaces, such as the sidewalls, horizontal surfaces, and the top of the sacrificial gate structure 60, respectively. In some embodiments, the insulating material layer has a thickness in a range from about 5 nm to about 20 nm. The insulating material layer includes one or more of SiN, SiON and SiCN or any other suitable dielectric material. The insulating material layer can be formed by ALD or CVD, or any other suitable method. Next, horizontal portions of the insulating material layer are removed by anisotropic etching, thereby forming the gate sidewall spacers. In some embodiments, the gate sidewall spacers include two to four layers of different insulating materials.

Then, one or more source/drain epitaxial layers are formed over the source/drain regions of the fin structures 20. In some embodiments, the source/drain regions of the fin structures 20 are recessed, and then the epitaxial layers are formed. Further, one or more interlayer dielectric (ILD) layers are formed, and a gate replacement process is performed to replace the sacrificial gate structure 60 with a metal gate structure.

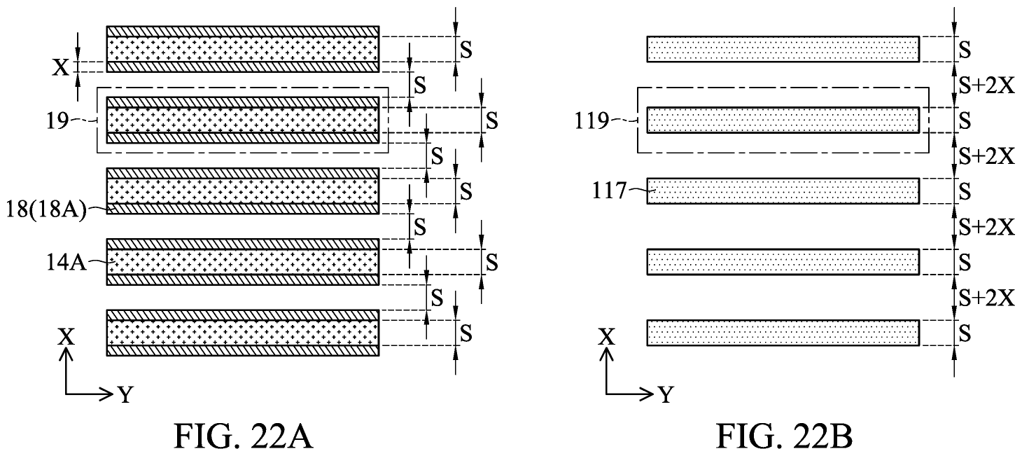

FIG. 22A shows a plan view of the structure shown in FIG. 5. FIG. 22B shows a layout pattern 117 corresponding to the mandrel pattern 14A and the photo resist pattern 17 of FIG. 1. FIG. 22A also shows a second mask pattern 19 for the fin cut process, and FIG. 22B shows a layout pattern 119 corresponding to the second mask pattern 19.

As shown in FIG. 22A, the second hard mask patterns 18 (or 18A) correspond to the fin structures 20, and have width x and space S to the adjacent pattern in the X direction. Thus, the fin structures (second hard mask patterns 18A) have a constant pitch (x+S). On the pattern layout, the mandrel patterns 117 are designed to have a width S and space S+2x as shown in FIG. 22B.

When the mandrel pattern size S, i.e., a space between the second hard mask patterns 18A, becomes smaller, the fin etching process as shown in FIGS. 12 and 13 becomes more difficult, resulting in, for example, insufficient bottom separation between adjacent fin structures. In addition, the narrow fin space may cause etching residue in the polysilicon etching process as shown in FIGS. 20-21. In the following embodiments, the mandrel spaces are locally expanded to obtain a greater space between adjacent fin structures (adjacent second hard mask patterns 18A).

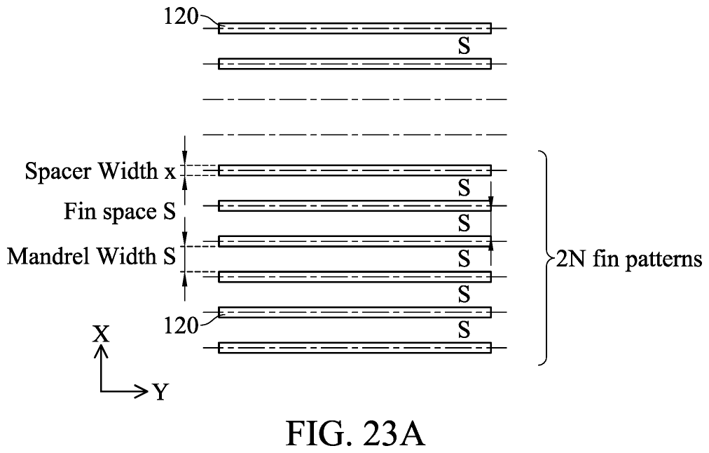

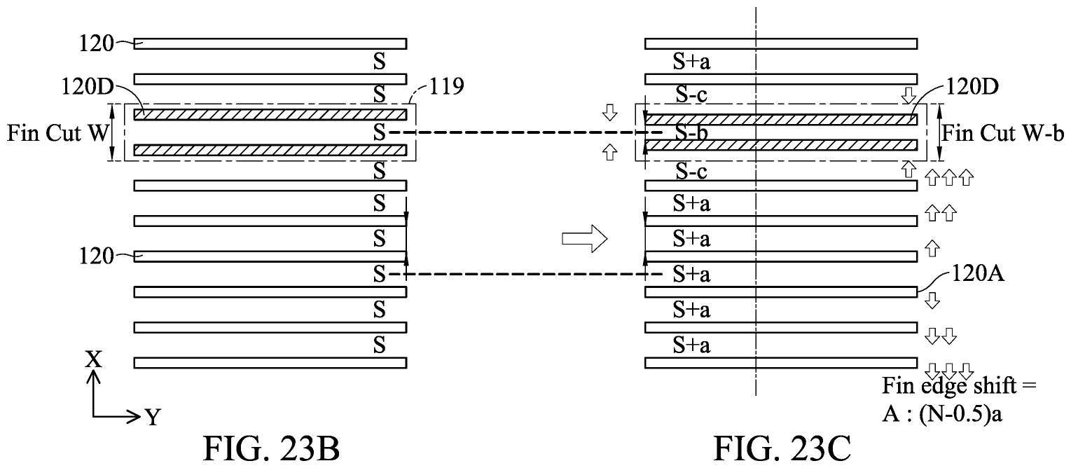

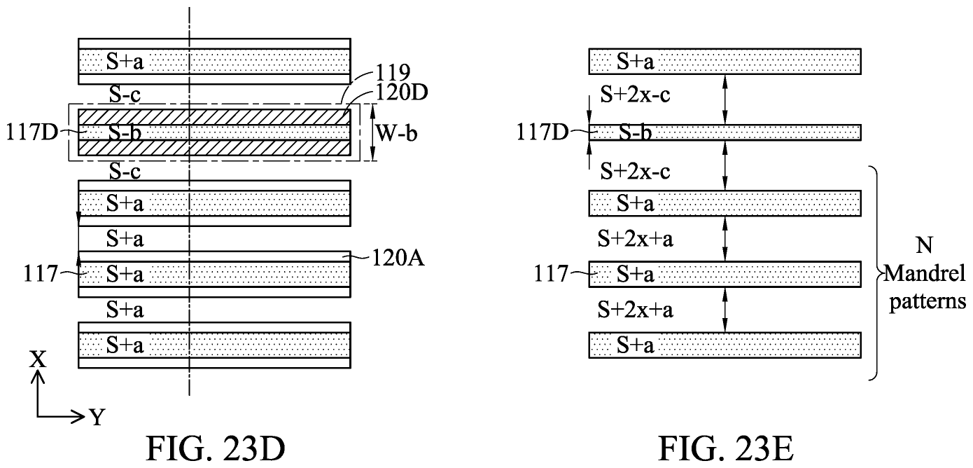

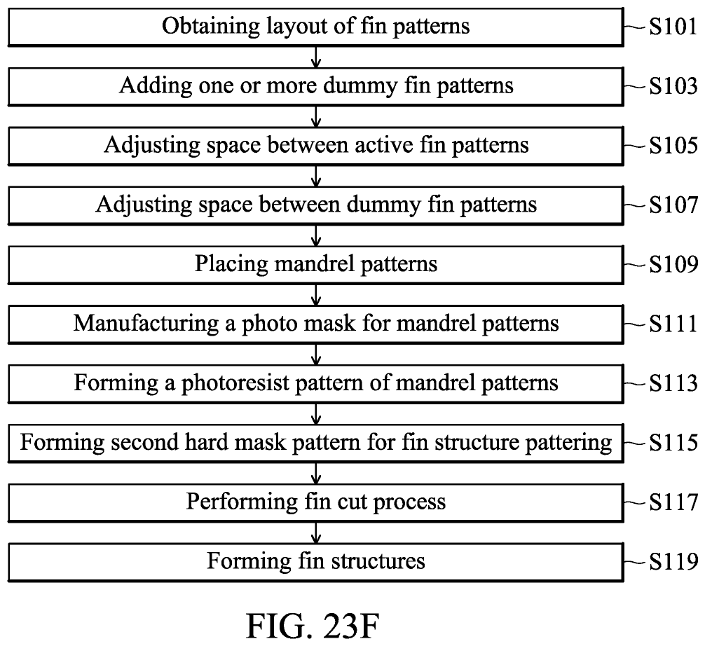

FIGS. 22A and 22B and 23A-23E show a layout pattern modification for the mandrel patterns according to an embodiment of the present disclosure. FIG. 23F is a flow chart of modifying the mandrel patterns.

FIG. 22A illustrates a layout showing mandrel patterns 14A and the second hard mask patterns 18A and FIG. 22B shows a layout of the mandrel pattern 117 only. FIGS. 22A and 22B also show a layout of the fin cut pattern 119 corresponding to the second mask pattern 19.

In S101 of FIG. 23F, an original pattern layout including fin patterns 120 is obtained. In some embodiments, the fin patterns 120 are designed based on a predetermined grid and arranged with a constant pitch along the X direction except for locations where no fin structure is necessary as shown in FIG. 23A. Each fin pattern corresponds to an active region (a source, a channel and a drain) of an FET. In some embodiments, as shown in FIG. 23A, the fin patterns 120 have a width x and a space S between adjacent fin patterns (i.e., a pitch is x+S). In some embodiments, the number of active fin patterns 120 arranged with the constant pitch is 2N (N is a natural number), and in some embodiments, N is an odd number.

Then, at S103 of FIG. 23F, one or more dummy fin patterns 120D are placed (generated) by a mask design system so that all the fin patterns are arranged with a constant pitch, as shown in FIG. 23B. In some embodiments, a fin cut pattern 119 corresponding to the photo resist pattern 19 of FIG. 7 is also generated over the dummy fin patterns 120D. The fin cut pattern 119 has a width W, and in some embodiments, W=2(x+S) and the longitudinal edges are located at the middle of the dummy fin pattern 120 and the active fin pattern 120 i.e., symmetric along the X direction).

Next, at S105 of FIG. 23F, spaces between the active fin patterns 120 are adjusted, for example, increased by the amount of “a” as shown in FIG. 23C. In some embodiments, the center location (along the X direction) of the N-th active fin pattern and the (N+1)-th active fin pattern from the dummy fin pattern 120D is fixed, and the locations of the N-th active fin pattern and the (N+1)-th active fin pattern are moved by the mask design system so that the space between the N-th active fin pattern and the (N+1)-th active fin pattern becomes S+a. The remaining active fin patterns are also moved to have the space S+a between the adjacent active fin patterns 120. In some embodiments, the both ends of the 2N fin patterns, the active fin patterns are moved by ±A=(N−0.5)×a. In some embodiments, the amount “a” is about 1% to about 10% of the original width S, and is about 2% to about 6% of S in other embodiments.

Then, at S107 of FIG. 23F, the width S between the dummy fin patterns 120D is adjusted, e.g., decreased by the amount “b” as shown in FIG. 23C. In some embodiments, the amount “b” is zero. In other embodiments, the amount “b” is more than zero and equal to or less than about 10% of the original width S. Further, the space S between the dummy fin pattern 120D and the adjacent active fin pattern 120 is adjusted, e.g., reduced by the amount “c” as shown in FIG. 23C. In some embodiments, the amount “c” is (A−b)/2. In other embodiments, the amount “c” is about 1% to or about 10% of the original width S. In addition, in some embodiments, the width W of the fin cut pattern 119 is also reduced by the amount “b” as shown in FIG. 23C.

Then, at S109 of FIG. 23F, mandrel patterns 117 and a dummy mandrel pattern 117D are generated such that the longitudinal edges of the mandrel patterns matches longitudinal edges of the corresponding fin patterns, as shown in FIG. 23D. As shown in FIG. 23D, the mandrel patterns are alternately placed in the spaces between adjacent fin patterns. FIG. 23E shows a layout of the mandrel patterns only. As shown in FIG. 23E, the active mandrel patterns 117 have the width of S+a and the space S+2x+a adjacent to the active mandrel pattern. Also, the dummy mandrel pattern 117D has the width of S-b and the space S+2x−c adjacent to the active mandrel pattern.

In some embodiments, when N is an even number, the center location (along the X direction) between the N/2-th mandrel pattern 117A and (N+1)/2-th mandrel pattern 117 from the dummy mandrel pattern 117B is fixed, and the longitudinal edges of the mandrel patterns 117A are shifted so that the active mandrel patterns 117A have the width of S+a and the space adjacent to the active mandrel of S+2x+a.

In some embodiments, the amounts of “a”, “b” and/or “c” are determined based on the resolution limit of a lithography operation for forming the mandrel pattern (see, FIG. 1). In some embodiments, the width S-b is greater than the resolution limit, for example 1.05-1.2 times or more of the resolution limit. In some embodiments, the amount “a” is determined first and after the amount “c” is determined, the amount “b” is determined.

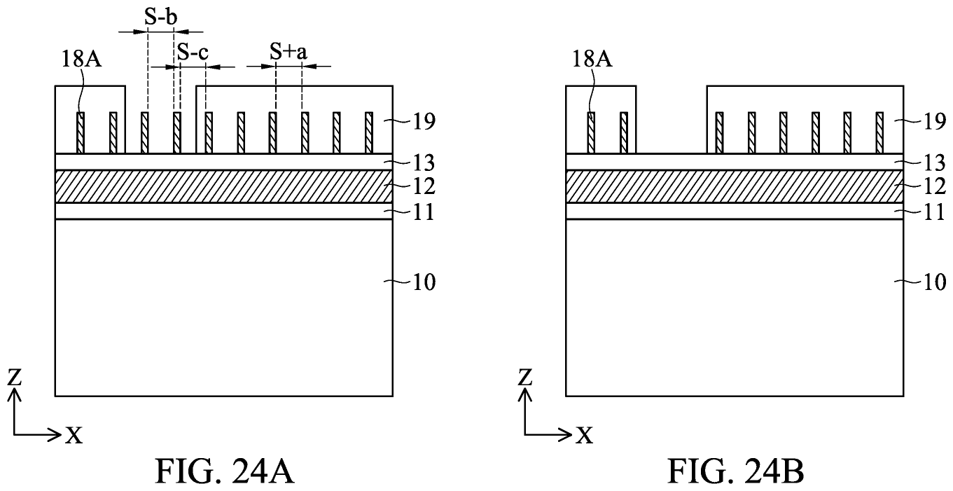

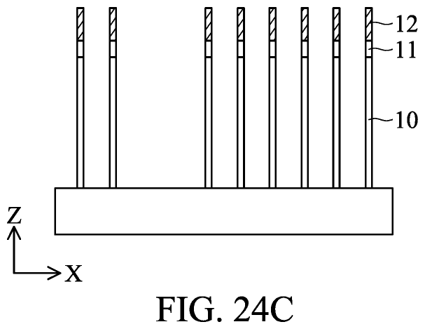

Next, a photo mask for the mandrel patterns is formed from the modified mandrel pattern layout as shown in FIG. 23E. A photo mask for the fin cut process for the pattern 19 is also manufactured from the adjusted fin cut pattern 119. Then, a resist pattern 17 as shown in FIG. 1 is formed using the photo mask at S113 of FIG. 23F. Further, at S115 of FIG. 23F, the second hard mask patterns 18A are formed as shown in FIG. 6. Subsequently, at S117 of FIG. 23F, the fin cut process shown in FIGS. 24A and 24B consistent with FIGS. 7-8 is performed, by using the photo mask manufactured from the adjusted fin cut pattern 119. Then, at S119 of FIG. 23F, the fin structures are formed by one or more etching operations as shown in FIG. 24C consistent with FIGS. 9-13.

As shown in FIG. 23C, by the aforementioned width/space adjustment of the fin patterns including dummy fin patterns, the space between adjacent fin patterns 120 is expanded from S to S+a, and thus patterning of the fin structure becomes easier by suppressing the residue between adjacent fin structures. Even though the space between dummy fin patterns is smaller than S, the second hard mask patterns 18A corresponding to the dummy fin patterns are removed by the fin cut process, and thus the residue issue between fin structures in the fin etching (FIGS. 13 and 24C) can be resolved.

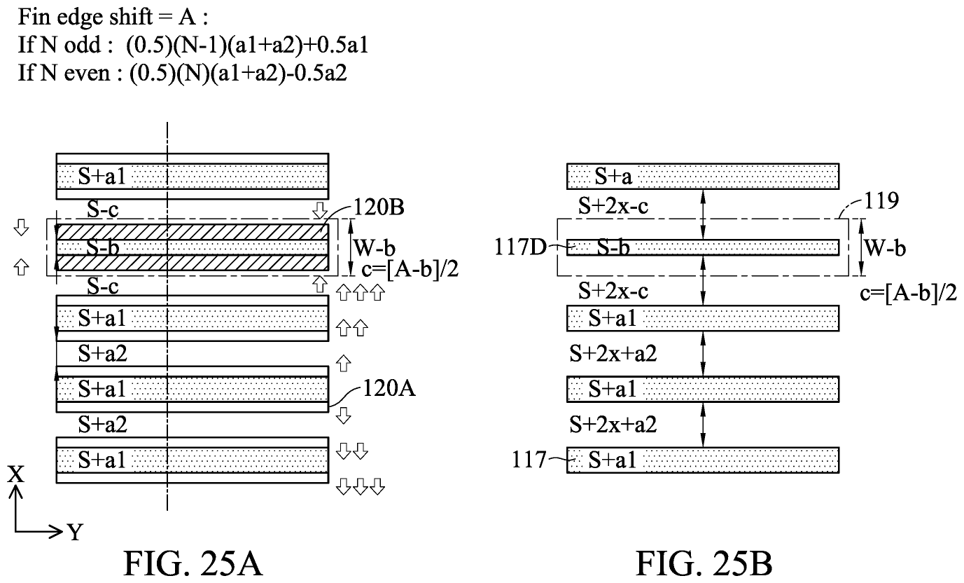

FIGS. 25A and 25B show a layout pattern modification according to an embodiment of the present disclosure. In some embodiments, the space S between the active fin patterns disposed on both longitudinal edges of the active mandrel pattern 117 (corresponding to mandrel-space MS) is increased by the amount “a1” and the space S between adjacent active fin patterns corresponding to the longitudinal edges of two adjacent active mandrel patterns 117 is increased by the amount “a2” different from “a1.” As shown in FIG. 25A, this adjustment is equivalent to expanding the mandrel-space MS (see FIG. 6) by the amount “a1” and the spacer-space SS by the amount of “a2.” The amounts of “a1” and “a2” are determined in view of variations in patterning the mandrel pattern or other patterning operations in some embodiments. For example, as explained with respect to FIG. 6, the mandrel-space MS may be different from the spacer-space SS depending on one or more process conditions or variations. In some embodiments, by adjusting the amounts of “a1” and/or “a2” in view of the dimension difference between MS and SS which would otherwise occur, it is possible to obtain substantially equal space widths between MS and SS. In some embodiments, the edge shift amount “A” is A=(N−1)/2×(a1+a2)+0.5a1 for odd N, and A=N/2×(a1+a2)−0.5a2 for even N.

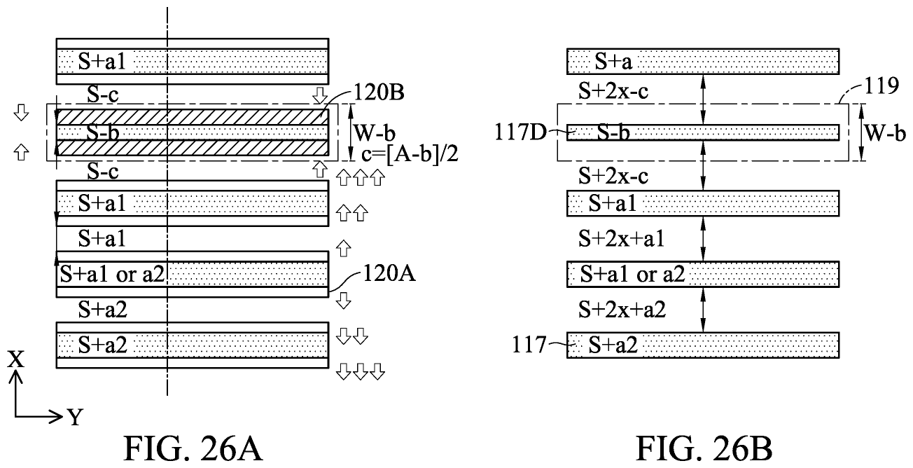

FIGS. 26A and 26B show a layout pattern modification according to an embodiment of the present disclosure. In some embodiments, the space S between adjacent active fin patterns 120 of N active fin patterns closer to the dummy fin pattern 120D is increased by the amount “a1,” and the space S between adjacent active fin patterns 120 of N active fin patterns farther from the dummy fin pattern 120D is increased by the amount “a2,” as shown in FIG. 26A. The width S between the N-th and the (N+1)-th active fin patterns is increased by either “a1” or “a2” in some embodiments.

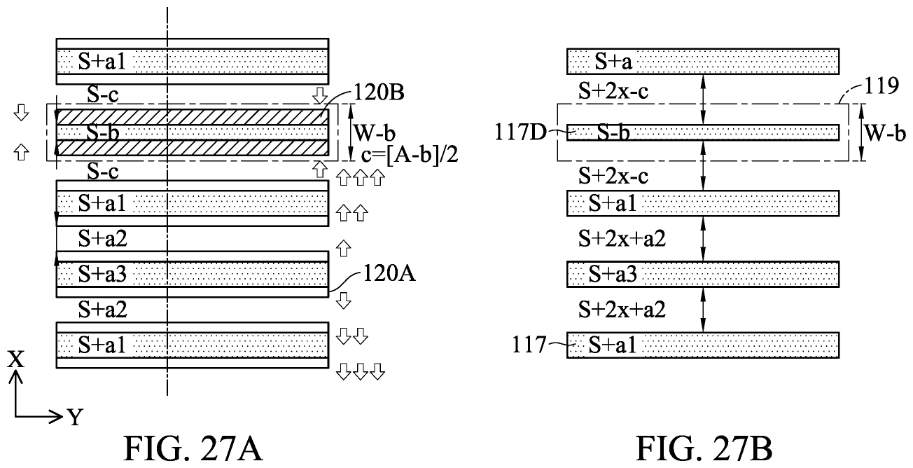

FIGS. 27A and 27B show a layout pattern modification according to an embodiment of the present disclosure. In some embodiments, the space S between adjacent fin patterns corresponding to the mandrel-space MS is increased by the amount “a1” and the space S between adjacent fin patterns corresponding to the spacer-space SS is increased by the amount “a2” except for the space S between the N-th and the (N+1)-th active fin patterns, which is increased by the amount of “a3.”

As set forth above, by introducing different adjustment amounts a1, a2 and/or a3, it is possible to more flexibly adjust the mandrel patterns and/or fin patterns in view of the process variations.

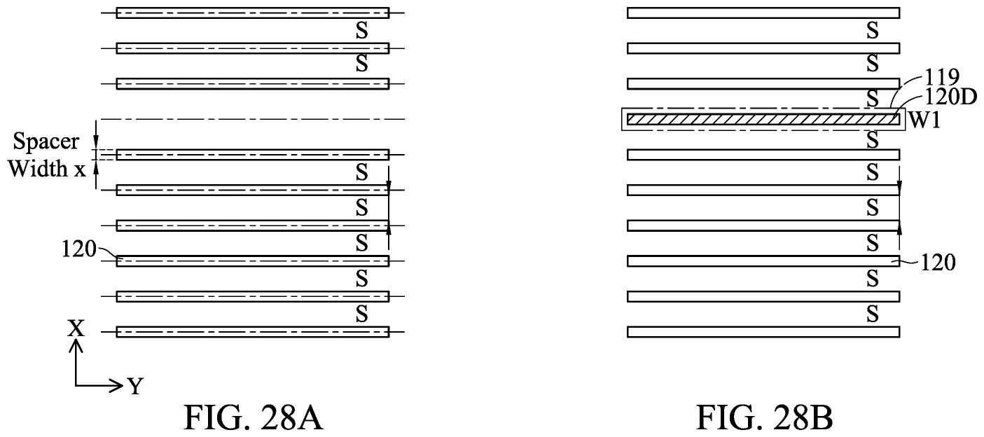

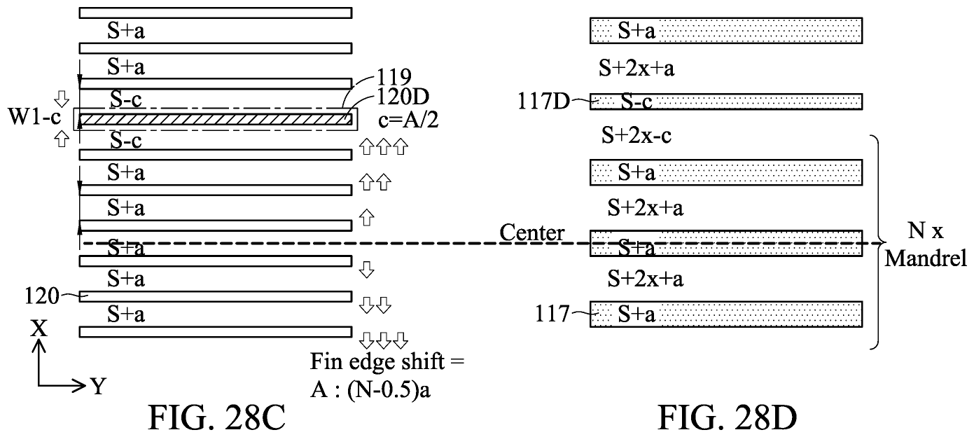

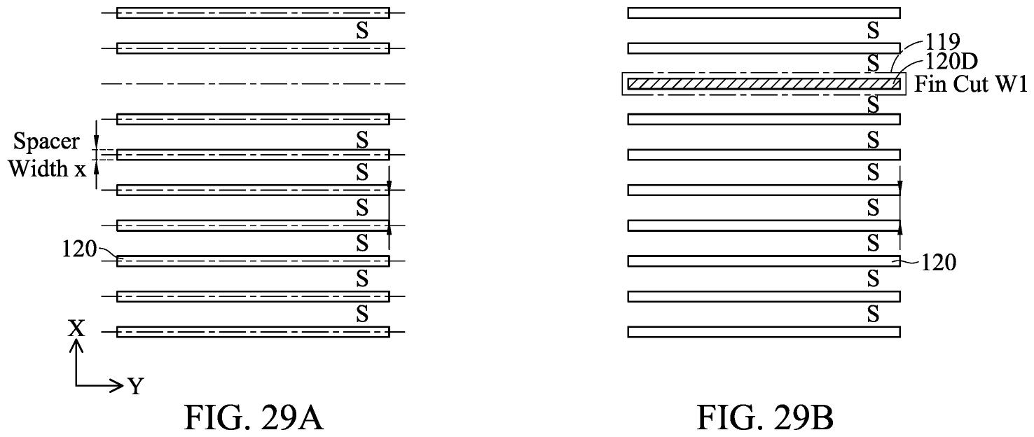

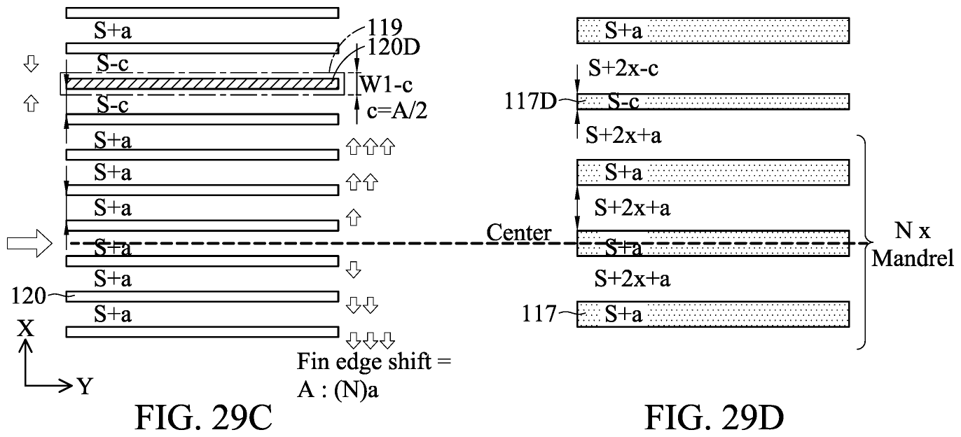

FIGS. 28A-28D and FIGS. 29A-29D show layout pattern modifications according to embodiments of the present disclosure. In some embodiments, one dummy fin pattern 120D is inserted between the active fin patterns 120. Similar to the foregoing embodiments, the original fin pattern layout as shown in FIG. 29A is obtained by a mask layout system, and then a dummy fin pattern 120D is generated by the mask layout system as shown in FIG. 29B. Then, the space S between adjacent active fin patterns is increased by the amount of “a,” and the space S between the dummy fin pattern and the adjacent active fin pattern is reduced by the amount of “c.” Further, in some embodiments, the width W1 of the fin cut pattern is also reduced by the amount of “c” where c=A/2. In case of FIGS. 28A-28D, A=(N−0.5)×a, and in case of FIGS. 29A-29D, A=N×a, in some embodiments.

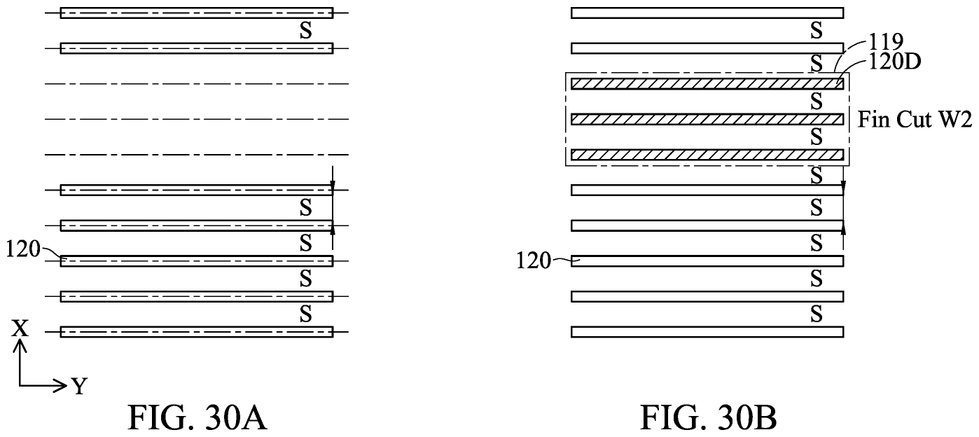

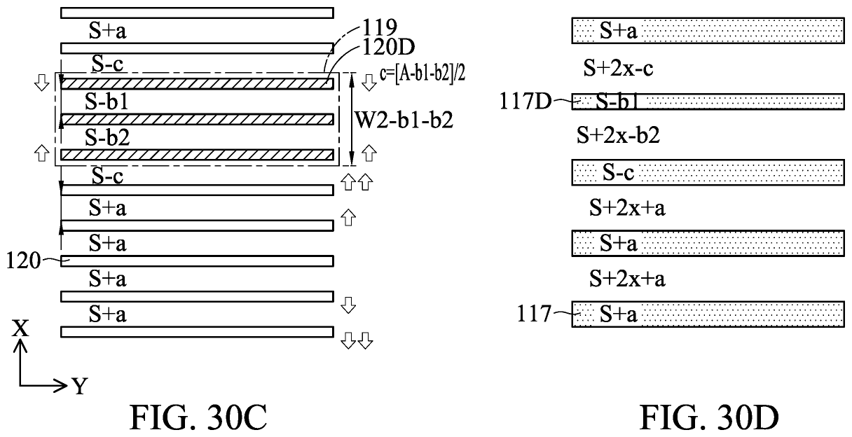

FIGS. 30A-30D show a layout pattern modification according to an embodiment of the present disclosure. In some embodiments, three dummy fin patterns are inserted between the active fin patterns. Similar to the foregoing embodiments, the original fin pattern layout as shown in FIG. 30A is obtained by a mask layout system, and then three dummy fin patterns 120D are generated by the mask layout system as shown in FIG. 30B.

Then, the space S between adjacent active fin patterns is increased by the amount of “a,” and the space S between the dummy fin pattern and the adjacent active fin pattern is reduced by the amount of “c.” The space S between the dummy fin pattern and the adjacent active fin pattern is reduced by the amount of “c.” Further, the space S between the dummy fin patterns corresponding to the mandrel-space MS is reduced by the amount “b1” and the space S between the dummy fin patterns corresponding to the spacer-space SS is reduced by the amount of “b2.” Further, in some embodiments, the width W2 of the fin cut pattern is also reduced by the amount of “b1+b2.” In some embodiments, c=(A−b1−b2)/2, where A=N×a.

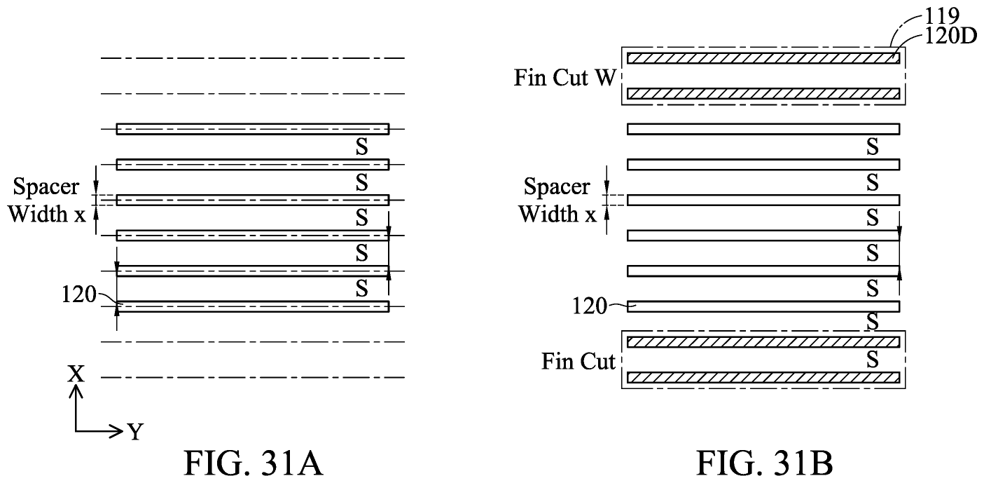

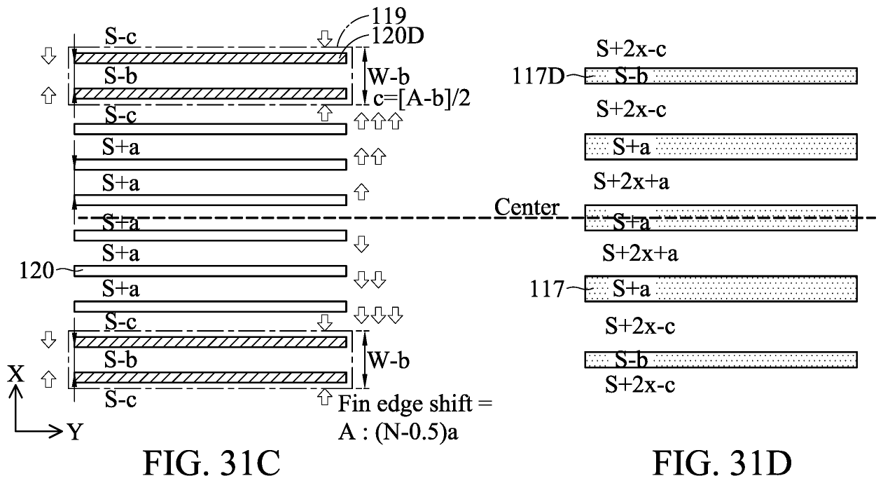

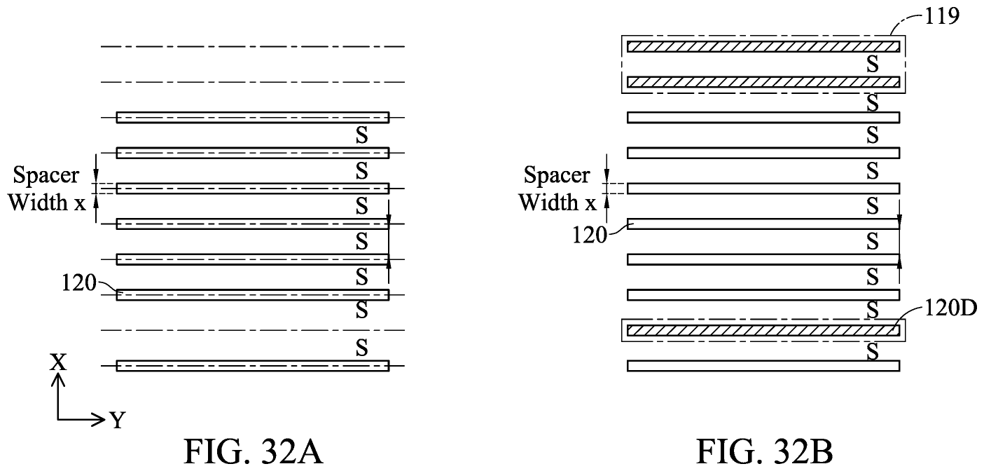

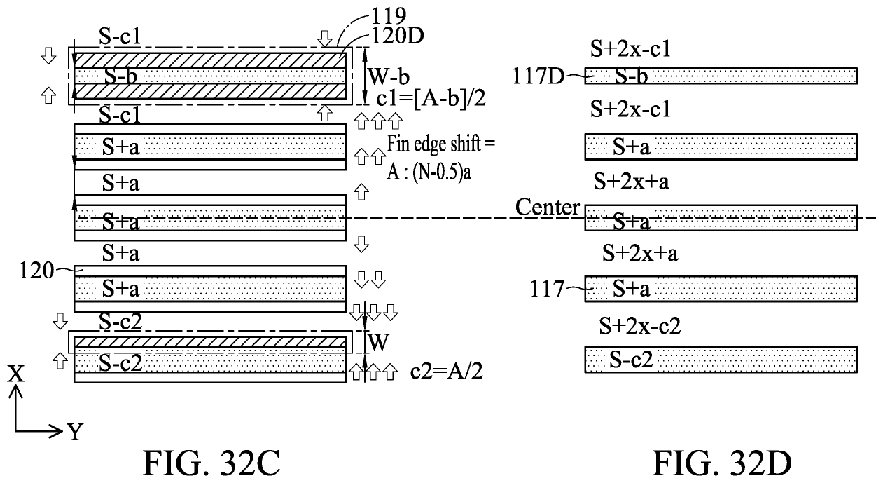

FIGS. 31A-31D and FIGS. 32A-32D show layout pattern modifications according to embodiments of the present disclosure. In some embodiments, active N fin patterns are disposed between dummy fin patterns along the X direction. In FIGS. 31A-31D, two pairs of dummy fin patterns 120D are generated by the mask layout system and inserted in the original layout of FIG. 31A, as shown in FIG. 31B. Then, the fin pattern locations are adjusted similar to the operations as explained with respect to FIGS. 23A-23D. Any of the adjustment values a1, a2 and/or a3 explained with respect to FIGS. 23A-27B can be applied to FIG. 31A-31D. In FIGS. 32A-32D, which is the combination of FIGS. 23A and 23B and FIGS. 28A-28D, the locations of the fin patterns are adjusted similar to the operations as explained with respect to FIGS. 23A-23D and FIGS. 28A-28D.

In the foregoing embodiments, the layout adjustments are explained by location adjustments of the fin patterns. However, it is possible to adjust layout patterns of the mandrel patterns 117 after the initial mandrel patterns having the width and space S are placed between the fin patterns including the dummy fin patterns of the original locations.

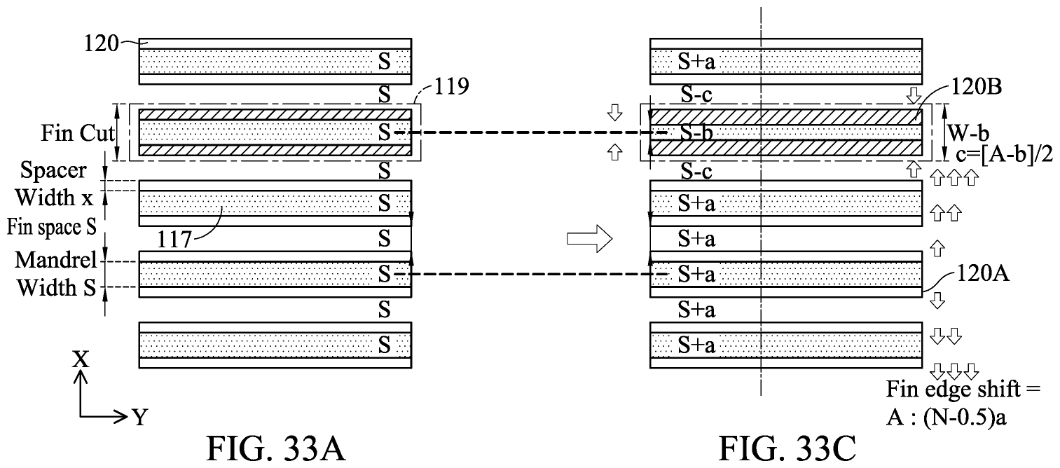

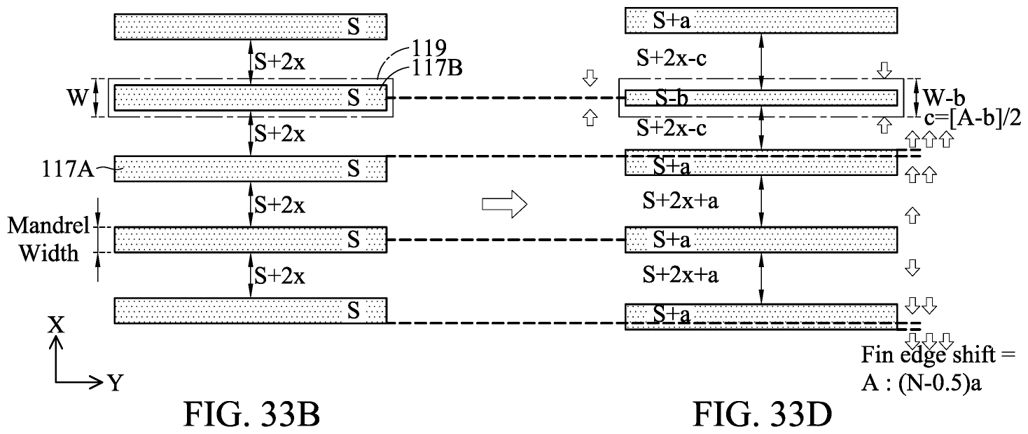

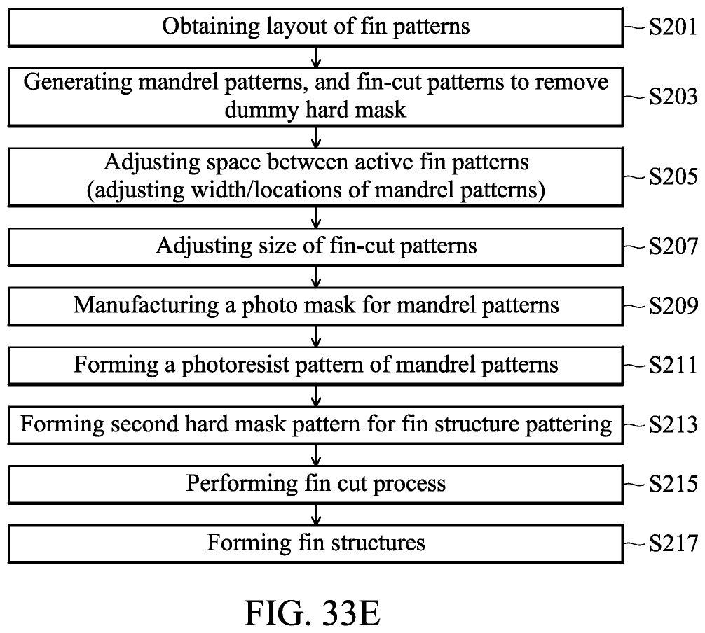

FIGS. 33A-33D show a layout pattern modification for the mandrel patterns according to an embodiment of the present disclosure. FIG. 33E is a flow chart of modifying the mandrel patterns. Processes, materials, dimensions, operations and/or configurations explained with respect to the foregoing embodiments can be applied to the following embodiments, and the detailed description thereof may be omitted.

In S201 of FIG. 33E, similar to S101 above, an original pattern layout including fin patterns 120 as shown in FIG. 23A is obtained.

Then, at S203 of FIG. 33E, mandrel patterns 117 and one or more dummy fin patterns 120D are placed (generated) by a mask design system so that all the fin patterns are arranged with a constant pitch, as shown in FIG. 33A. The mandrel patterns are placed so that the longitudinal edges of the mandrel patterns correspond to the active fin patterns. If one or more longitudinal edges of the mandrel pattern have no corresponding active fin patterns, one or more dummy fin patterns are placed on such longitudinal edges. In some embodiments, a fin cut pattern 119 corresponding to the photo resist pattern 19 of FIG. 7 is also generated over the dummy fin patterns 120D. The fin cut pattern 119 has a width W, and in some embodiments, W=2(x+S) and the longitudinal edges are located at the middle of the dummy fin pattern 120 and the active fin pattern 120 i.e., symmetric along the X direction). FIG. 33B shows only the mandrel patterns 119 and the fin cut pattern 119.

Next, at S205 of FIG. 33E, spaces between the fin patterns are adjusted as shown in FIG. 33C. In some embodiments, this is done by adjusting widths of the mandrel patterns 117 as shown in FIG. 33D. In some embodiments, the width S of the mandrel patterns for the active fin patterns is increased to S+a, while the width S of the mandrel patterns for the dummy fin patterns is decreased to S-b. Thus, the space S+2x between the mandrel patterns for the active fin patterns is S+2x+a, and the space between the mandrel pattern for the active fin patterns and the mandrel pattern for the dummy fin patterns is S+2x−c, where c=(A-b)/2, and A=(N−0.5)×a. In some embodiments, the location (along the X direction) of the central mandrel pattern(s) is fixed, and the edges of the mandrel patterns are moved. In some embodiments, the edge of the mandrel pattern at the end portion is moved by A=(N−0.5)×a. In some embodiments, the amount “a” is about 1% to about 10% of the original width S, and is about 2% to about 6% of S in other embodiments.

Then, at S207 of FIG. 33E, the width W of the fun cut pattern 119 is adjusted to W-b.

S209, S211, S213, S215 and S217 are the same as S109, S111, S113, S115 and S117 of FIG. 23F.

The flow of FIG. 33E is also applied to the cases of FIGS. 25A-26B, FIGS. 27A-27B, FIGS. 28A-28D, FIGS. 29A-29D, FIGS. 30A-30D, FIGS. 31A-31D and FIGS. 32A-32D.

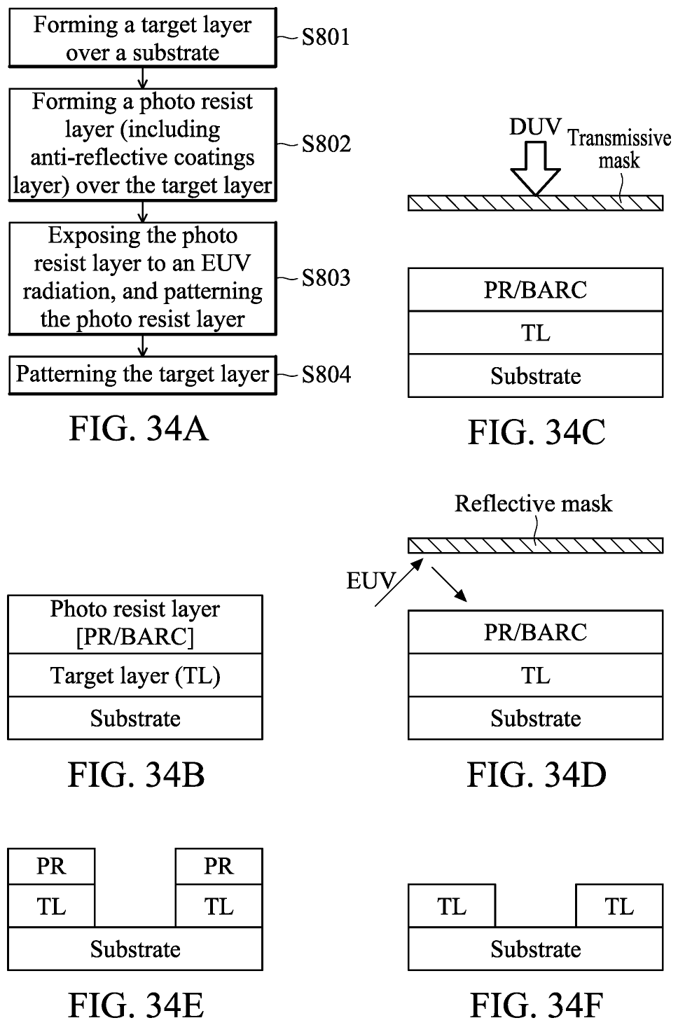

FIG. 34A shows a flowchart of a method of making a semiconductor device, and FIGS. 34B, 34C, 34D, 34E and 34F show a sequential manufacturing operation of the method of making a semiconductor device in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. At S801 of FIG. 34A, a target layer to be patterned is formed over the semiconductor substrate. In certain embodiments, the target layer is the semiconductor substrate. In some embodiments, the target layer includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer is formed over an underlying structure, such as isolation structures, transistors or wirings. At S802 of FIG. 34A, a photo resist layer is formed over the target layer, as shown in FIG. 34B. The photo resist layer is sensitive to the radiation from the exposing source during a subsequent photolithography exposing process. The photo resist layer may be formed over the target layer by spin-on coating or other suitable techniques. The coated photo resist layer may be further baked to drive out solvent in the photo resist layer.

At S803 of FIG. 34A, the photoresist layer is patterned using an optical lithography tool. In some embodiments, the optical lithography tool is an ArF or a KrF excimer laser scanner (DUV scanner) using a transmissive mask as shown in FIG. 34C. The transmissive mask includes the mandrel patterns of which dimensions are adjusted as explained above. In other embodiments, the optical lithography tool is an EUV scanner using a reflective mask including the mandrel patterns of which dimensions are adjusted, as shown in FIG. 34D. During the exposing process, the integrated circuit (IC) design pattern defined on the mask is imaged to the photoresist layer to form a latent pattern thereon. The patterning of the photoresist layer further includes developing the exposed photoresist layer to form a patterned photoresist layer having one or more openings. In one embodiment where the photoresist layer is a positive tone photoresist layer, the exposed portions of the photoresist layer are removed during the developing process. The patterning of the photoresist layer may further include other process steps, such as various baking steps at different stages. For example, a post-exposure-baking (PEB) process may be implemented after the photolithography exposing process and before the developing process.

At S804 of FIG. 34A, the target layer is patterned utilizing the patterned photoresist layer as an etching mask, as shown in FIG. 34E. In some embodiments, the patterning the target layer includes applying an etching process to the target layer using the patterned photoresist layer as an etch mask. The portions of the target layer exposed within the openings of the patterned photoresist layer are etched while the remaining portions are protected from etching. Further, the patterned photoresist layer may be removed by wet stripping or plasma ashing, as shown in FIG. 34F.

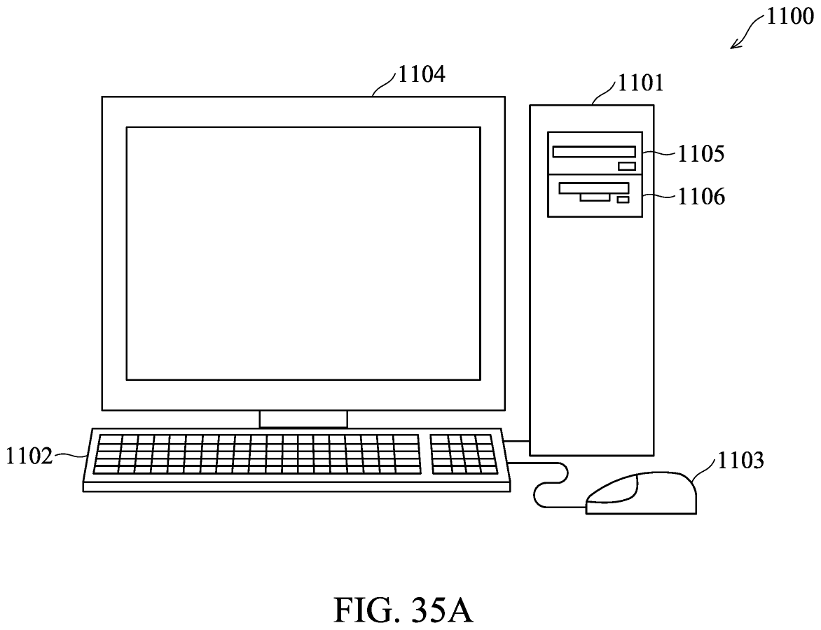

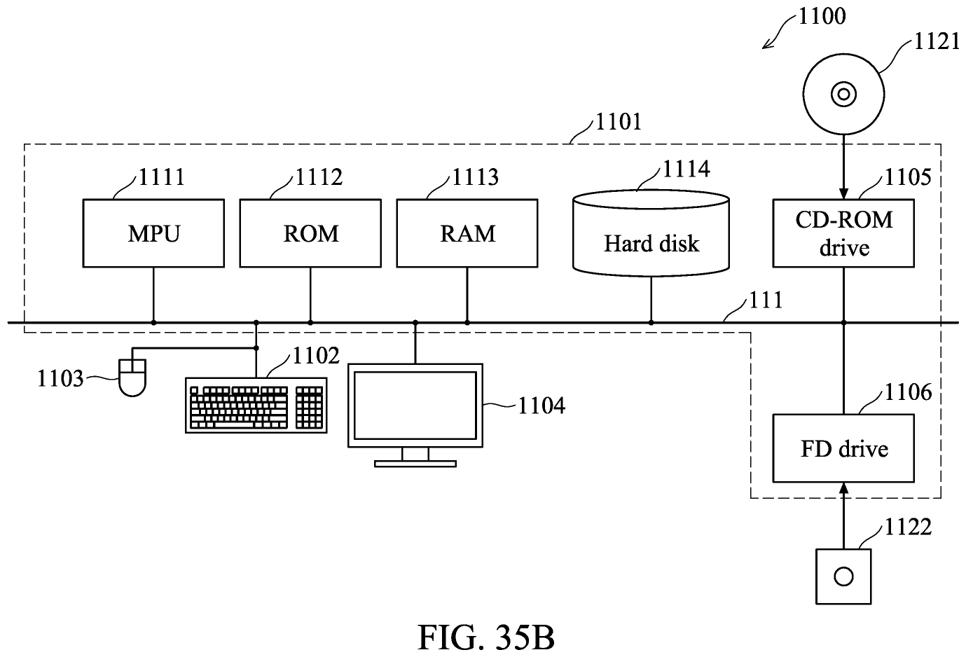

FIGS. 35A and 35B illustrate an apparatus for manufacturing a lithographic mask for a semiconductor circuit in accordance with some embodiments of the disclosure. In some embodiments, the apparatus is an optical simulator.

FIG. 35A is a schematic view of a computer system (mask layout system) that executes the process for manufacturing the lithographic mask according to one or more embodiments as described above. All of or a part of the processes, method and/or operations of the foregoing embodiments can be realized using computer hardware and computer programs executed thereon. The operations include pattern layout adjustments as explained above. In FIG. 35A, a computer system 1100 is provided with a computer 1101 including an optical disk read only memory (e.g., CD-ROM or DVD-ROM) drive 1105 and a magnetic disk drive 1106, a keyboard 1102, a mouse 1103, and a monitor 1104.

FIG. 35B is a diagram showing an internal configuration of the computer system 1100. The computer 1101 is provided with, in addition to the optical disk drive 1105 and the magnetic disk drive 1106, one or more processors 1111, such as a micro processing unit (MPU), a ROM 1112 in which a program, such as a boot up program is stored, a random access memory (RAM) 1113 that is connected to the MPU 1111 and in which a command of an application program is temporarily stored and a temporary storage area is provided, a hard disk 1114 in which an application program, a system program, and data are stored, and a bus 1115 that connects the MPU 1111, the ROM 1112, and the like. Note that the computer 1101 may include a network card (not shown) for providing a connection to a LAN.

The program for causing the computer system 1100 to execute the process for adjusting the mandrel pattern dimensions (and/or fin pattern location adjustments) in the foregoing embodiments may be stored in an optical disk 1121 or a magnetic disk 1122, which are inserted into the optical disk drive 1105 or the magnetic disk drive 1106, and transmitted to the hard disk 1114. Alternatively, the program may be transmitted via a network (not shown) to the computer 1101 and stored in the hard disk 1114. At the time of execution, the program is loaded into the RAM 1113. The program may be loaded from the optical disk 1121 or the magnetic disk 1122, or directly from a network. The program does not necessarily have to include, for example, an operating system (OS) or a third party program to cause the computer 1101 to execute the process for manufacturing the lithographic mask of a semiconductor device in the foregoing embodiments. The program may only include a command portion to call an appropriate function (module) in a controlled mode and obtain desired results.

The various embodiments or examples described herein offer several advantages over the existing art. For example, in the present disclosure, the dimensions of active mandrel patterns (width and/or space), on which longitudinal edges active fin structures are formed, are increased, while the increased amounts are partially or fully compensated by the dimensions of the dummy mandrel pattern, it is possible to improve process margins and suppress various issues which would otherwise be caused by narrow spaces between fin patterns.

It will be understood that not all advantages have been necessarily discussed herein, no particular advantage is required for all embodiments or examples, and other embodiments or examples may offer different advantages.

In accordance with one aspect of the present disclosure, in a method of manufacturing a semiconductor device, an initial pattern layout is obtained by using a computer. The initial pattern layout incudes fin patterns which include active fin patterns to be formed as active fin structures and dummy fin patterns not to be formed as actual fin structures or to be removed. The locations of the fin patterns are modified by using the computer, as follows. A space between adjacent active fin patterns is increased by a first amount, a space between the dummy fin patterns is decreased by a second amount, and a space between one of the dummy fin patterns and one of the active fin patterns adjacent to the one of the dummy fin patterns is decreased by a third amount. Mandrel patterns are placed by the computer so that the fin patterns of which locations are modified are placed along longitudinal edges of the mandrel patterns. A photo mask is manufactured based on the mandrel patterns, and a photo resist pattern is formed using the photo mask over an underlying layer. In one or more of the foregoing or the following embodiments, the first amount is 1% to 10% of the space between adjacent active fin patterns before the modification. In one or more of the foregoing or the following embodiments, the mandrel patterns include active mandrel patterns and a dummy mandrel pattern, the active mandrel patterns are placed so that the active fin patterns are placed along longitudinal edges of the active mandrel pattern, respectively, and the dummy mandrel pattern is placed so that the dummy fin patterns are placed along longitudinal edges of the dummy mandrel pattern. In one or more of the foregoing or the following embodiments, the third amount is (an edge shift amount−the second amount)/2, where the edge shift amount is ((a number of the active fin patterns arranged with a constant pitch and located on one side of the dummy mandrel pattern)/2+0.5)×the first amount. In one or more of the foregoing or the following embodiments, the second amount is equal to zero. In one or more of the foregoing or the following embodiments, the second amount is more than zero and equal to or less than 10% of the space between the dummy fin patterns before the modification. In one or more of the foregoing or the following embodiments, the third amount is 1% to 10% of the space between one of the dummy fin patterns and one of the active fin patterns adjacent to the one of the dummy fin patterns before the modification.

In accordance with another aspect of the present disclosure, in a method of manufacturing a semiconductor device, a first photo resist pattern is formed using a first photo mask over a sacrificial layer disposed over a hard mask layer disposed over a substrate, sacrificial patterns are formed by patterning the sacrificial layer, sidewall patterns are formed on sidewalls of the sacrificial patterns, the sacrificial patterns are removed, thereby leaving the sidewall patterns as first hard mask patterns, the hard mask layer is patterned by using the first hard mask patterns as an etching mask, thereby forming second hard mask patterns, and the substrate is patterned by using the second hard mask patterns as an etching mask, thereby forming fin structures. The first photo mask is obtained as follows. An initial pattern layout is obtained by using a computer. The initial pattern layout incudes fin patterns which include active fin patterns to be formed as active fin structures and dummy fin patterns not to be formed as actual fin structures or to be removed. The locations of the fin patterns are modified by using the computer, as follows. A space between adjacent active fin patterns is increased by a first amount, a space between the dummy fin patterns is decreased by a second amount, and a space between one of the dummy fin patterns and one of the active fin patterns adjacent to the one of the dummy fin patterns is decreased by a third amount. Mandrel patterns are placed by the computer so that the fin patterns of which locations are modified are placed along longitudinal edges of the mandrel patterns. The photo mask is manufactured based on the mandrel patterns. In one or more of the foregoing or the following embodiments, before the hard mask layer is patterned, a part of the first hard mask patterns is removed by using one or more lithography and etching operations, in which a second photo mask is used. The part of the first hard mask patterns includes patterns corresponding to the dummy fin patterns and the second photo mask is obtained based on a layout of the dummy fin patterns. In one or more of the foregoing or the following embodiments, the sacrificial patterns are made of poly silicon. In one or more of the foregoing or the following embodiments, the first hard mask patterns are made of silicon nitride. In one or more of the foregoing or the following embodiments, the hard mask layer includes multiple layers of dielectric materials. In one or more of the foregoing or the following embodiments, the sidewall patterns are formed by conformally forming a blanket layer by atomic layer deposition, and performing anisotropic etching to remove a horizontal part of the blanket layer.

In accordance with another aspect of the present disclosure, in a method of manufacturing a semiconductor device, a first hard mask layer is formed over a substrate, a sacrificial layer is formed over the first hard mask layer, a second hard mask layer is formed over the sacrificial layer, first hard mask patterns are formed by patterning the second hard mask layer, sacrificial patterns are formed by patterning the sacrificial layer using the first hard mask patterns as an etching mask, sidewall patterns are formed on sidewalls of the sacrificial patterns, the sacrificial patterns are removed, thereby leaving the sidewall patterns as second hard mask patterns, part of the second hard mask patterns is removed, after the part of the second hard mask is removed, the hard mask layer is patterned by using a remaining part of the second hard mask patterns as an etching mask, thereby forming third hard mask patterns, and the substrate is patterned by using the third hard mask patterns as an etching mask, thereby forming fin structures. The part of the second hard mask patterns that are removed includes dummy hard mask patterns having a space S1 and the remaining part of the second hard mask patterns includes active hard mask patterns having a space S2 between adjacent active hard mask patterns, and S1 is smaller than S2. In one or more of the foregoing or the following embodiments, a space S3 between one of the dummy hard mask patterns and one of the active hard mask patterns closest to the dummy hard mask patterns is smaller than S2. In one or more of the foregoing or the following embodiments, S2 is S+ΔS1, where ΔS1 is 1% to 10% of S, and S1 is S−ΔS2, where ΔS2 is 0% to 10% of S. In one or more of the foregoing or the following embodiments, S3 is S+ΔS3, where ΔS3 is 1% to 10% of S. In one or more of the foregoing or the following embodiments, an additional hard mask layer is further formed over the second hard mask layer. In one or more of the foregoing or the following embodiments, an additional hard mask layer is further formed over the third hard mask patterns. In one or more of the foregoing or the following embodiments, the first hard mask layer includes a first layer formed on the substrate, a second layer formed on the first layer and made of a different material than the first layer and a third layer formed on the second layer and made of a different material than the second layer.

In accordance with another aspect of the present disclosure, in a method of manufacturing a photo mask, an initial pattern layout is obtained by using a computer. The initial pattern layout incudes fin patterns which include active fin patterns to be formed as active fin structures and dummy fin patterns not to be formed as actual fin structures or to be removed. The locations of the fin patterns are modified by using the computer, as follows. A space between adjacent active fin patterns is increased by a first amount, a space between the dummy fin patterns is decreased by a second amount, and a space between one of the dummy fin patterns and one of the active fin patterns adjacent to the one of the dummy fin patterns is decreased by a third amount. Mandrel patterns are placed by the computer so that the fin patterns of which locations are modified are placed along longitudinal edges of the mandrel patterns. A photo mask is manufactured based on the mandrel patterns.

In accordance with another aspect of the present disclosure, a mask layout system includes a processor and a non-transitory memory storing a program. The program, when executed by the processor, causes the processor to perform the following operations. An initial pattern layout is received. The initial pattern layout incudes fin patterns which include active fin patterns to be formed as active fin structures and dummy fin patterns not to be formed as actual fin structures or to be removed. The locations of the fin patterns are modified, as follows. A space between adjacent active fin patterns is increased by a first amount, a space between the dummy fin patterns is decreased by a second amount, and a space between one of the dummy fin patterns and one of the active fin patterns adjacent to the one of the dummy fin patterns is decreased by a third amount. Mandrel patterns are placed so that the fin patterns of which locations are modified are placed along longitudinal edges of the mandrel patterns. The mandrel patterns are output.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
obtaining, by using a computer, an initial pattern layout comprising fin patterns, the fin patterns including active fin patterns to be formed as active fin structures and dummy fin patterns not to be formed as actual fin structures or to be removed;
modifying, by the computer, locations of the fin patterns by:
increasing a space between adjacent active fin patterns by a first amount;
decreasing a space between the dummy fin patterns by a second amount; and
decreasing a space between one of the dummy fin patterns and one of the active fin patterns adjacent to the one of the dummy fin patterns by a third amount;
placing, by the computer, mandrel patterns so that the fin patterns of which locations are modified are placed along longitudinal edges of the mandrel patterns;
manufacturing a photo mask based on the mandrel patterns; and
forming a photo resist pattern using the photo mask over an underlying layer.

2. The method of claim 1, wherein the first amount is 1% to 10% of the space between adjacent active fin patterns before the modification.

3. The method of claim 1, wherein:
the mandrel patterns include active mandrel patterns and a dummy mandrel pattern,
the active mandrel patterns are placed so that the active fin patterns are placed along longitudinal edges of the active mandrel pattern, respectively, and
the dummy mandrel pattern is placed so that the dummy fin patterns are placed along longitudinal edges of the dummy mandrel pattern.

4. The method of claim 3, wherein the third amount is (an edge shift amount−the second amount)/2, where the edge shift amount is ((a number of the active fin patterns arranged with a constant pitch and located on one side of the dummy mandrel pattern)/2+0.5)×the first amount.

5. The method of claim 4, wherein the second amount is equal to zero.

6. The method of claim 4, wherein the second amount is more than zero and equal to or less than 10% of the space between the dummy fin patterns before the modification.

7. The method of claim 4, wherein the third amount is 1% to 10% of the space between one of the dummy fin patterns and one of the active fin patterns adjacent to the one of the dummy fin patterns before the modification.

8. A method of manufacturing a semiconductor device, comprising:
forming a first photo resist pattern using a first photo mask over a sacrificial layer disposed over a hard mask layer disposed over a substrate
forming sacrificial patterns by patterning the sacrificial layer;
forming sidewall patterns on sidewalls of the sacrificial patterns;
removing the sacrificial patterns, thereby leaving the sidewall patterns as first hard mask patterns;
patterning the hard mask layer by using the first hard mask patterns as an etching mask, thereby forming second hard mask patterns; and
patterning the substrate by using the second hard mask patterns as an etching mask, thereby forming fin structures,
wherein the first photo mask is obtained by:
obtaining, by using a computer, an initial pattern layout comprising fin patterns the fin patterns including active fin patterns to be formed as active fin structures and dummy fin patterns not to be formed as actual fin structures or to be removed;
modifying, by the computer, locations of the fin patterns by:
increasing a space between adjacent active fin patterns by a first amount;
decreasing a space between the dummy fin patterns by a second amount; and
decreasing a space between one of the dummy fin patterns and one of the active fin patterns adjacent to the one of the dummy fin patterns by a third amount;
placing, by the computer, mandrel patterns so that the fin patterns of which locations are modified are placed along longitudinal edges of the mandrel patterns; and
manufacturing the first photo mask based on the mandrel patterns.

9. The method of claim 8, further comprising, before the hard mask layer is patterned:
removing a part of the first hard mask patterns by using one or more lithography and etching operations, in which a second photo mask is used,
wherein the part of the first hard mask patterns includes patterns corresponding to the dummy fin patterns and the second photo mask is obtained based on a layout of the dummy fin patterns.

10. The method of claim 9, wherein the sacrificial patterns are made of poly silicon.

11. The method of claim 10, wherein the first hard mask patterns are made of silicon nitride.

12. The method of claim 9, wherein the hard mask layer includes multiple layers of dielectric materials.

13. The method of claim 9, wherein the sidewall patterns are formed by conformally forming a blanket layer by atomic layer deposition, and performing anisotropic etching to remove a horizontal part of the blanket layer.

14. A method of manufacturing a semiconductor device, comprising:
forming a first hard mask layer over a substrate;
forming a sacrificial layer over the first hard mask layer;
forming a second hard mask layer over the sacrificial layer;
forming first hard mask patterns by patterning the second hard mask layer;
forming sacrificial patterns by patterning the sacrificial layer using the first hard mask patterns as an etching mask;
forming sidewall patterns on sidewalls of the sacrificial patterns;
removing the sacrificial patterns, thereby leaving the sidewall patterns as second hard mask patterns;
removing part of the second hard mask patterns;
after the removing part of the second hard mask, patterning the hard mask layer by using a remaining part of the second hard mask patterns as an etching mask, thereby forming third hard mask patterns; and
patterning the substrate by using the third hard mask patterns as an etching mask, thereby forming fin structures,
wherein the part of the second hard mask patterns that are removed includes dummy hard mask patterns having a space S1 and the remaining part of the second hard mask patterns includes active hard mask patterns having a space S2 between adjacent active hard mask patterns, and
S1 is smaller than S2.

15. The method of claim 14, wherein a space S3 between one of the dummy hard mask patterns and one of the active hard mask patterns closest to the dummy hard mask patterns is smaller than S2.

16. The method of claim 15, wherein S2 is S+ΔS1, where ΔS1 is 1% to 10% of S, and S1 is S−ΔS2, where ΔS2 is 0% to 10% of S.

17. The method of claim 16, wherein S3 is S+ΔS3, where ΔS3 is 1% to 10% of S.

18. The method of claim 14, further comprising forming an additional hard mask layer over the second hard mask layer.

19. The method of claim 18, further comprising forming an additional hard mask layer over the third hard mask patterns.

20. The method of claim 19, wherein the first hard mask layer includes a first layer formed on the substrate, a second layer formed on the first layer and made of a different material than the first layer and a third layer formed on the second layer and made of a different material than the second layer.
